(19) United States
(12) Patent Application Publication
(10) Pub. No.: US 2026/0332161 A1
(43) Pub. Date: Oct. 22, 2026

(54) METHOD AND DEVICE FOR EFFICIENT LATENT REPRESENTATION CODING BASED ON CHANNEL SKIPPING TECHNIQUE FOR AI-BASED COMPRESSION MODELS

(71) Applicant: Electronics and Telecommunications Research Institute, Daejeon (KR)

(72) Inventors: Soo Woong KIM, Daejeon (KR); Jun Sik KIM, Daejeon (KR); Ji Hoon DO, Daejeon (KR); Gun BANG, Daejeon (KR); Seong Jun BAE, Daejeon (KR); Ha Hyun LEE, Daejeon (KR); Jung Won KANG, Daejeon (KR); Jin Soo CHOI, Daejeon (KR)

(73) Assignee: Electronics and Telecommunications Research Institute, Daejeon (KR)

(21) Appl. No.: 19/577,509

(22) Filed: Mar. 25, 2026

(30) Foreign Application Priority Data
Mar. 25, 2025 (KR) 10-2025-0037749
Mar. 24, 2026 (KR) 10-2026-0052757

(51) Int. Cl. H03M 7/30

(52) U.S. Cl. CPC H03M 7/3082; H03M 7/6005; H03M 7/6011

(57) ABSTRACT

A device, a method and a recording medium for encoding/decoding a latent representation may include obtaining flag information representing whether each channel is active from a bitstream; based on the flag information, obtaining data corresponding to an active channel; and based on the flag information, reconstructing a latent representation having an overall channel structure by filling an inactive channel with a predetermined value.

### REFERENCE TO RELEVANT APPLICATION

This application claims priority and benefits on the prior application date for Korean Patent Application No. 10-2025-0037749 filed on Mar. 25, 2025 and Korean Patent Application No. 10-2026-0052757 filed on Mar. 24, 2026, and the contents of the applications are incorporated herein by reference in their entirety.

### TECHNICAL FIELD

The present disclosure belongs to a deep learning-based data compression technology field, and in particular, relates to a method and a device for maximizing compression efficiency and optimizing encoding complexity by utilizing a channel-based skip technique during latent representation encoding in a general data compression process. The present invention may be applied to the compression of voice, time-series data, 3D models and other structured or unstructured data as well as images and videos.

### BACKGROUND ART

With the rapid development of 3D sensors including a 3D scanner, LiDAR, a vision-based 3D reconstruction technology, etc., the technical field of the 3D graphic content has significantly grown. Furthermore, as a result of sensor-based data collection, a point cloud, is a raw 3D data format defined by a series of points, has been widely distributed.

Each point of a point cloud may be expressed in a position by using 3D coordinates. A point cloud is a single set, and may represent the geometry of an object or a scene. Optionally, each point in a point cloud may be connected to a different attribute according to an application. An example may include the RGB color of an immersive application such as VR and AR, the reflectance of LiDAR for autonomous driving and robotics, etc. Point cloud data may enable further processing for more perfect 3D modeling such as mesh expression. In addition, point cloud data may also be directly utilized in a machine-centered follow-up cognitive task such as detection, recognition, etc.

A point cloud may often consist of a series of frames representing a dynamic object or a dynamic scene. In particular, it may correspond to a case for an immersive application such as AR and VR and LiDAR for autonomous driving and robotics. The recent AI technologies have demonstrated cutting-edge performance in the point cloud compression field. However, unlike processing, improvement, rendering and recognition tasks, AI-based point cloud compression has not been widely used due to a lack of standards.

### DISCLOSURE

### Technical Problem

The present disclosure is to reduce unnecessary encoding targets, improve encoding/decoding speed and enhance overall compression performance by efficiently processing a deactivated channel in an AI-based compression model. Through this, it is to enable efficient compression even in a low bit-rate environment and reduce the operation amount, thereby increasing usability in real-time application.

### Technical Solution

A device, a method and a recording medium for encoding/decoding the latent representation of the present disclosure may include obtaining flag information representing whether each channel is active from a bitstream; based on the flag information, obtaining data corresponding to an active channel; and based on the flag information, reconstructing a latent representation having an overall channel structure by filling an inactive channel with a predetermined value.

In a device, a method and a recording medium for encoding/decoding the latent representation of the present disclosure, the flag information may be constructed in a form of a binary vector representing whether each channel is active.

In a device, a method and a recording medium for encoding/decoding the latent representation of the present disclosure, the inactive channel may be filled with a value of 0.

In a device, a method and a recording medium for encoding/decoding the latent representation of the present disclosure, the data corresponding to the active channel may be restored through entropy decoding.

In a device, a method and a recording medium for encoding/decoding the latent representation of the present disclosure, the reconstruction step may include inserting the data corresponding to the active channel and filling the inactive channel to form the overall channel structure.

In a device, a method and a recording medium for encoding/decoding the latent representation of the present disclosure, the flag information may be used as control information for performing selective decoding in a channel unit.

### Technical Effect

The present disclosure may provide the following effects to improve the performance of an AI-based data compression model.

Maximize Compression Efficiency: By excluding an unnecessary channel from an encoding process, the compression rate may be improved and storage space may be saved. It may be optimized to enable high-quality restoration even at a low bit rate.

Reduce Amount of Operation and Improve Speed: The computational complexity is reduced by decreasing the amount of data that needs to be processed during encoding and decoding processes. Performance may be optimized to enable fast encoding and decoding in a real-time application environment.

Support Adaptive Data Compression: The optimal compression efficiency may be achieved by dynamically determining a channel to be encoded according to the characteristics of input data. It may be applied to various data types (images, voice, time-series data, 3D models, etc.), resulting in high versatility.

Maintain Performance in Low Bit Rate Environment: It is optimized to maintain higher compression efficiency and quality than before even at a low bit rate. High efficiency may be demonstrated even in a restricted transmission environment such as IoT, mobile devices and cloud streaming.

### BRIEF DESCRIPTION OF DRAWINGS

FIG. 1 illustrates an example of a 4-bit binary tree structure storing a voxel.

FIG. 2 illustrates an example of an octree structure for a voxel.

FIG. 3 illustrates an example of the arrangement of a coding unit in a bitstream.

FIG. 4 illustrates an example of the overall decoding process.

FIG. 5 illustrates an example of lossless decoding and lossy decoding in a geometry decoding process.

FIG. 6 illustrates an example of an ancestor occupancy analysis step.

FIG. 7 illustrates an example of a feature decoding step.

FIG. 8 illustrates an example of a sparse 3D convolution-based point synthesis method.

FIG. 9 illustrates an example of an occupancy decoding step.

FIG. 10 illustrates an embodiment of a learning-based motion decoding process.

FIG. 11 illustrates an embodiment of an inter predictor derivation step.

FIG. 12 illustrates an example of a motion compensation step.

FIG. 13 illustrates an example of the overall encoding process.

FIG. 14 illustrates an example of lossless encoding and lossy encoding in a geometry encoding process.

FIG. 15 illustrates an example of a feature encoding step.

FIG. 16 illustrates an example of an occupancy encoding step.

FIG. 17 illustrates an embodiment of a learning-based motion encoding process.

FIG. 18 illustrates an embodiment of an inter predictor derivation step.

FIG. 19 illustrates an embodiment of a block diagram for a channel skip-based latent representation encoding/decoding method.

FIG. 20 illustrates an embodiment of the operation of a Skip Flag Generation module.

FIG. 21 illustrates an embodiment of the operation of a Latent Pruning module.

FIG. 22 illustrates an embodiment of the operation of a Latent Reassemble module.

### MODE FOR INVENTION

As the present disclosure may make various changes and have multiple embodiments, specific embodiments are illustrated in a drawing and are described in detail in a detailed description. But, it is not to limit the present disclosure to a specific embodiment, and should be understood as including all changes, equivalents and substitutes included in the idea and technical scope of the present disclosure. A similar reference numeral in a drawing refers to a like or similar function across multiple aspects. The shape and size, etc. of elements in a drawing may be exaggerated for a clearer description. A detailed description on exemplary embodiments described below refers to an accompanying drawing which shows a specific embodiment as an example. These embodiments are described in detail so that those skilled in the pertinent art can implement an embodiment. It should be understood that a variety of embodiments are different each other, but they do not need to be mutually exclusive. For example, a specific shape, structure and characteristic described herein may be implemented as another embodiment without departing from the scope and spirit of the present disclosure in connection with an embodiment. In addition, it should be understood that the position or arrangement of an individual component in each disclosed embodiment may be changed without departing from the scope and spirit of an embodiment. Accordingly, a detailed description described below is not taken as a limited meaning and the scope of exemplary embodiments, if properly described, is limited only by an accompanying claim along with any scope equivalent to that claimed by those claims.

In the present disclosure, a term such as first, second, etc. may be used to describe a variety of components, but the components should not be limited by the terms. The terms are used only to distinguish one component from other components. For example, without departing from the scope of a right of the present disclosure, the first component may be referred to as the second component and likewise, the second component may be also referred to as the first element. A term of and/or includes a combination of a plurality of relevant described items or any of a plurality of relevant described items.

When a component in the present disclosure is referred to as being “linked” or “connected” to another component, it should be understood that it may be directly linked or connected to that another component, but another component may exist in the middle. On the other hand, when a component is referred to as being “directly linked” or “directly connected” to another component, it should be understood that another component does not exist in the middle.

As construction units shown in the embodiment of the present disclosure are independently shown to represent different characteristic functions, it does not mean that each construction unit is constructed in the construction unit of separate hardware or one software. In other words, as each construction unit is included by being enumerated as each construction unit for convenience of description, at least two construction units of each construction unit may be combined to form one construction unit or one construction unit may be divided into a plurality of construction units to perform a function, and the integrated embodiment and separate embodiment of each construction unit are also included in the scope of a right of the present disclosure unless they are beyond the essence of the present disclosure.

As a term used in the present specification is just used to describe a specific embodiment, it is not intended to limit the present disclosure. Expression of the singular includes expression of the plural unless it clearly has a different meaning contextually. In the present disclosure, it should be understood that a term such as “include” or “have”, etc. is to designate the existence of features, numbers, steps, motions, components, parts or combinations thereof described on the specification, but is not to exclude the existence or possibility of addition of one or more other features, numbers, steps, motions, components, parts or combinations thereof in advance. In other words, a description of “including” a specific configuration in the present disclosure does not exclude a configuration other than a corresponding configuration, and it means that an additional configuration may be included in the scope of a technical idea of the present disclosure or the embodiment of the present disclosure.

Some components of the present disclosure are not a necessary component which performs an essential function in the present disclosure and may be an optional component just for improving performance. The present disclosure may be implemented by including only a construction unit which is necessary to implement essence of the present disclosure except for a component used just for performance improvement, and a structure including only a necessary component except for an optional component used just for performance improvement is also included in the scope of a right of the present disclosure.

Hereinafter, the embodiment of the present disclosure will be described in detail by referring to drawings. In describing the embodiment of the present specification, when it is determined that a detailed description on a relevant disclosed configuration or function may obscure the gist of the present specification, such a detailed description is omitted, and the same reference numeral is used for the same component on a drawing and an overlapping description on the same component is omitted.

The present disclosure discloses the syntax, semantics and decoding process of point cloud data by using an artificial intelligence (AI)-based coding method. In addition, the present disclosure discloses a process necessary for point cloud reconstruction, and discloses additional processes such as a process after decoding, a process before reconstruction, a process after reconstruction, an adaptive process, etc.

The definition of terms used in the present disclosure may be as follows.

Augmented Reality (AR) may be an environment in which the content generated by a computer is superimposed on the real world viewed by a user.

Virtual Reality (VR) is a computer-generated environment in which realistic-looking scenes and objects exist, which makes a user feel immersed in the surrounding environment.

World Coordinate System may be a coordinate system in which a point cloud is captured. A world coordinate system may also be referred to as an original coordinate system.

Coding Coordinate System may be a coordinate system in which a point cloud is coded. In a coding coordinate system, geometry may have a non-negative number.

The definition of abbreviations in the present disclosure may be as follows.
AU: Access Unit
IDR: Instantaneous Decoding Refresh
IRAP: Intra Random Access Point
LSB: Least Significant Bit
MSB: Most Significant Bit
PCC: Point Cloud Compression
AI-PCC: AI-based Point Cloud Compression
Vector<a> may be a vector with a elements.
Matrix<r, c> may be a matrix with r rows and c columns.
Tensor<r, a> may be a sparse tensor designated as a-dimensional vector data for a 3D coordinate list. Here, spatial resolution in each of the x, y and z directions may be between 0 and 2^{r}−1. In addition, parameter a may be the number of feature channels associated with each 3D point.

Concat(T1, T2, T3, . . . ) may be a combination layer connected in a single order in the order that multiple tensors of T1, T2, T3, . . . are shown in a list. Here, all connected tensors must have the same resolution and may have a set of the same points. In addition, each tensor may have a different number of feature channels.

A rectified linear unit (ReLU) is a type of nonlinear activation function used in an artificial neural network, and may be referred to as a rectified linear unit. As an example, the function may output an input value as it is when an input value is greater than a threshold value, but otherwise (when an input value is less than or equal to a threshold value), may output 0.

Conv<a, b, c, d, e> may be a 3D convolution layer whose kernel size is a×a×a. Here, b may be a stride parameter, c may be a dilation size, d may be an input channel size, and e may be an output channel size.

Deconv<a, b, c, d, e> may be a 3D deconvolution layer whose kernel size is a×a×a. Here, b may be a stride parameter, c may be a dilation size, d may be an input channel size, and e may be an output channel size.

MLP<c₀, c₁, c₂, . . . , cₙ> may be multi-layer perceptrons (MLP) with n layers. Here, c₀ may be the size of an input channel, and cᵢ may be the size of the output channel of each layer (1≤i≤n).

A variable (or a term) related to the point cloud geometry of the present disclosure may be referred to as a point or a voxel. A point explicitly represents the position (x, y, z) of a sample, but may not designate the size of an occupied space. A voxel implicitly represents the position of a sample through a position in an octree and may represent a cube of a specific size. The center of a voxel may be used as the position of a corresponding point.

When point cloud geometry is expressed by points, each point cloud frame may be constructed by an array of 3D positions (x, y, z). Here, the coordinate values of 3D positions may be expressed as a signed integer in a world coordinate system. In addition, the coordinate values of 3D positions may be expressed as an n-bit unsigned integer in the shifted coding coordinate system of the present disclosure. Here, n is a bit depth, and may represent the precision of a point position. In addition, n may be explicitly determined by information signaled from a bitstream or may be implicitly determined by another point cloud-related information. In this case, the size of a 2ⁿ-sized cubic bounding box in which one edge is (0,0,0) and the opposite edge is (2ⁿ⁻¹, 2ⁿ⁻¹, 2ⁿ⁻¹) may be defined in a shifted coding coordinate system.

The scaled coding coordinate system of the present disclosure may be a coordinate system in which a shifted coding coordinate system is scaled to define a scaled coding coordinate system for compression. Whether scaling is applied, the degree of scaling, etc. may be explicitly determined by information signaled from a bitstream or may be implicitly determined by another point cloud-related information.

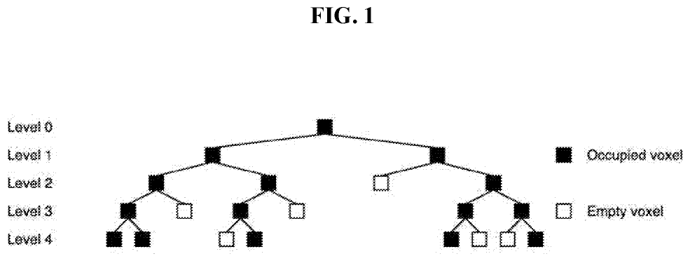

FIG. 1 illustrates an example of a 4-bit binary tree structure storing a voxel.

An octree (or an octree structure) is another method for expressing a point, which may partition a space in a hierarchical way. In point cloud geometry with n-bit coordinates, an octree may have a total of n+1 levels from 0 to n. Here, 0 may represent a root level. An octree which stores a voxel, 3D data, may be a tree structure in which each node has eight children.

Before describing an octree, referring to FIG. 1, since a binary tree structure in FIG. 1 is 4 bits, it may have a total of five levels from 0 to 4. In addition, each node represents a voxel, and an occupied voxel may have two child nodes.

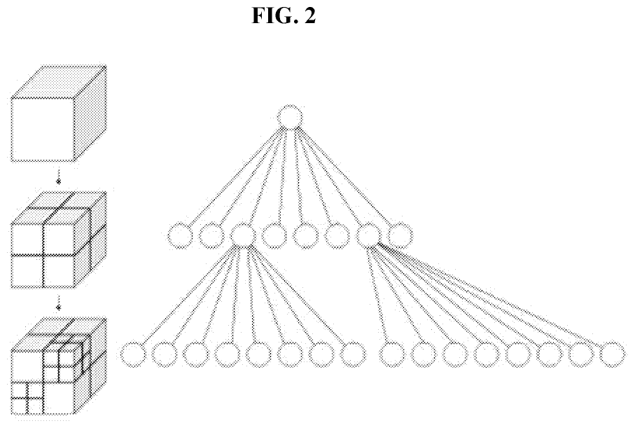

FIG. 2 illustrates an example of an octree structure for a voxel.

In an octree (or an octree structure), for octree level i=0 (a root level), a voxel may occupy the entire space within a point cloud bounding box. For each level, the space of a voxel occupied at a parent level may be equally partitioned in each of the x, y and z directions to generate eight child voxels of the same size. In other words, each child voxel may occupy ⅛ of the parent voxel space. Accordingly, a voxel size is determined according to octree level i to which a corresponding voxel belongs, and when normalized, it may be 2ⁿ⁻ⁱ or 2ⁿ⁻ⁱ/2ⁿ. In the present disclosure, a child voxel may also be expressed as an octant.

In the present disclosure, an occupied voxel may be expressed as a value of 1, and an empty voxel (an unoccupied voxel) may be expressed as a value of 0.

The occupancy map (or voxel occupancy map) Oⁱ of the present disclosure may represent a point cloud for octree level i. In addition, occupancy map Oⁱ may be expressed as Tensor<i, 1>. In this case, the spatial resolution of a tensor may be designated as current octree level i. A one-dimensional value for each point of a tensor may represent whether a voxel is occupied (=1) or empty (═0).

At a specific octree level, a voxelCount variable may be defined as the number of occupied voxels at a parent octree level. The variable may be obtained by a GetVoxelCountParent( ) function which counts the number of occupied voxels at a parent octree level.

The attribute of a point cloud may provide additional information related to each point of a source point cloud. When an attribute exists, each attribute may be connected to the corresponding point of a source point cloud. The attribute type of the present disclosure may include a color and reflectance.

The color attribute of the present disclosure may be expressed in an RGB color space. As an example, each color channel (red, green, blue) may be expressed as an 8-bit unsigned integer value within the range of [0, 255].

When point cloud geometry is expressed as an array of 3D positions (x, y, z), a color attribute may be expressed as an array with an extended field (x, y, z, r, g, b).

When point cloud geometry is expressed as an octree voxel, a color attribute may be expressed as tensor Tensor<n, 3>. Here, n may represent the bit depth of point cloud geometry. A 3D vector for each point of a tensor may represent an associated color value (r, g, b).

When point cloud geometry is expressed as an array of 3D positions (x, y, z), a reflectance attribute may be expressed as an array with an extended field (x, y, z, r). Here, r may represent reflectance.

When point cloud geometry is expressed as an octree voxel, a reflectance attribute may be expressed as tensor Tensor<n, 1>. Here, n may represent the bit depth of point cloud geometry. A one-dimensional scalar for each point of a tensor may represent associated reflectance value r.

The feature of a point cloud may be used as the latent representation of a neural network-based process during point cloud encoding and decoding processes. The feature of a point cloud may be used in a format other than an occupancy map in an encoded point cloud. The feature of a point cloud may not be included in a source point cloud or a decoded point cloud.

A set of features across all voxels within an occupancy map may be referred to as a feature map. At octree level i, a feature map may be expressed as Tensor<j, a>. Here, j represents the spatial resolution of feature map 2^{j}×2^{j}×2^{j}, which may be the same as or different from octree level i. Here, a may represent the number of feature channels.

Each point of a feature map may correspond to an occupied or empty voxel. Each point of a feature map may be associated with an a-dimensional feature vector. Each a-dimensional feature vector may encode geometry information for intra coding. Alternatively, it may encode temporal dynamics and motion patterns for inter prediction coding.

In addition, a feature map may be used for the lossy decoding of an occupancy map or to support lossless decoding.

The points of a point cloud may be ordered in a raster scanning order. Raster scanning may proceed first in a z direction, then in a y direction and finally in an x direction. It may be equivalent to ordering points in ascending order by using key value k calculated based on a point position (x, y, z). In this case, k may be x×2^{r+r}+y×2^{r}+z.

In addition, a raster scanning order may be used to map tensor T to a two-dimensional matrix M=Matrix<N, c> or vice versa.

A point cloud frame may be defined as a complete set of point cloud data representing a 3D scene or object at a specific time point. A point cloud sequence may consist of a series of point cloud frames.

A point cloud frame is partitioned into one or more point cloud slices, and a point cloud slice may be the spatial subunit of a frame. Each slice includes a subset of points within a frame, and generally, may be grouped according to spatial locality, coding efficiency or parallel processing requirements. Encoding of a point cloud frame may be performed by independently encoding each construction slice.

A data coding unit may have four types of a raw coding unit, a feature coding unit, an occupancy coding unit and a motion coding unit. When reproducible coding is enabled, a protection coding unit may be used additionally. All data coding units excluding a raw coding unit may be connected to a protection coding unit. This connection may decode corresponding data in a stable and consistent way, which may be particularly important for compatibility between platforms and a deterministic decoding motion.

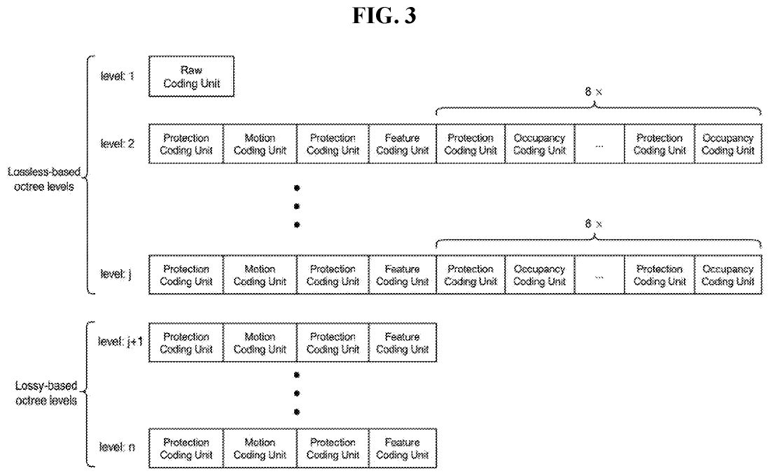

FIG. 3 illustrates an example of the arrangement of a coding unit in a bitstream.

A coding unit may be hierarchically constructed from octree level 1 to the last coded octree level. The last coded octree level may be different from the last octree level of an input point cloud.

At octree level i=0 corresponding to the root node of an octree structure, any data may not be explicitly coded in a bitstream. A root node may be always considered occupied by definition.

For octree level i=1, a raw coding unit may be used to encode the occupancy status of eight octants.

When a raw coding unit is used, 1 byte is used to encode the occupancy of eight octants, and each bit may correspond to one octant.

For octree level 1<i≤j, one feature coding unit may be present in a bitstream for each coded octree level. In addition, each level may encode eight occupancy coding units after encoding one feature coding unit. In other words, a feature coding unit may be used to assist an occupancy coding unit. Here, eight occupancy coding units may correspond to eight octants in a raster scan order ((0,0,0), (1,0,0), (0,1,0), (1,1,0), (0,0,1), (1,0,1), (0,1,1), (1,1,1)).

An occupancy coding unit may include encoded occupancy data representing the occupancy status of a voxel for a specific octant at a current octree level.

Referring to FIG. 3, lossless coded octree levels (or lossless-based octree levels) may represent octree level 1≤i≤j.

Referring to FIG. 3, lossy coded octree levels (or lossy-based octree levels) may represent octree level j<i≤n.

For octree level j<i≤n, each level may need to encode one feature coding unit. In addition, a feature coding unit may be used to derive an occupancy map through a point synthesis process with a lossy coding method. In addition, for lossy coded octree levels, an occupancy coding unit may not exist.

For an inter-coded frame, one motion coding unit must be inserted before a feature coding unit for each coded octree level with i>1.

A protection coding unit may be encoded in a bitstream to protect the decoding of a feature coding unit, an occupancy coding unit and a motion coding unit (all data coding units excluding a raw coding unit). Each protection coding unit is connected to a single data coding unit, and a connected single data coding unit may be a feature coding unit, an occupancy coding unit or a motion coding unit. The role of a protection coding unit may be to protect the reproducibility of related data during decoding. As an example, when protection for crossplatform reproducibility for a specific feature coding unit is enabled, a protection coding unit may be encoded in a bitstream to protect the decoding of the feature coding unit.

A motion coding unit may include encoded motion feature data representing the temporal dynamics between a current frame and a reference frame at a current octree level.

At each inter-coded octree level, one motion coding unit may exist in a bitstream. In addition, as in FIG. 3, a motion coding unit may take precedence over a feature coding unit at the same octree level.

A motion feature may be extracted, quantized and entropy-encoded by an encoder and stored in a bitstream. The motion feature may capture a temporal relationship and a motion pattern between two slices of a current frame and a decoded reference frame, respectively, at a current octree level.

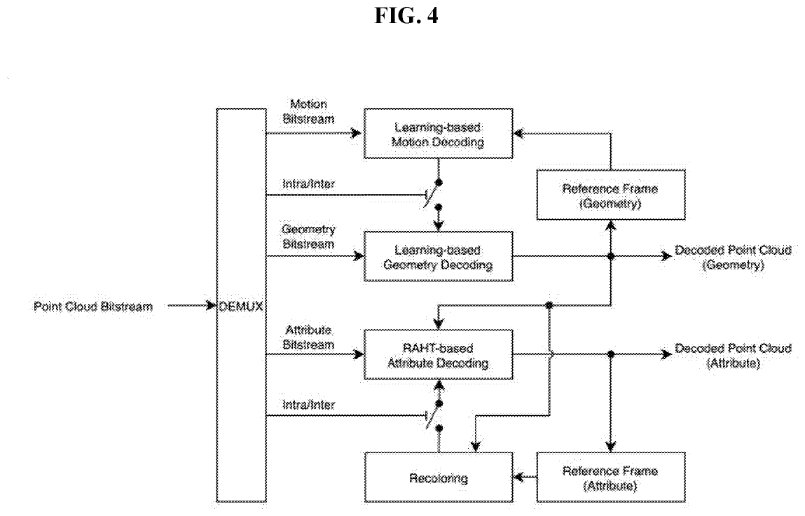

FIG. 4 illustrates an example of the overall decoding process.

The decoding process of the present disclosure may include learning-based point cloud geometry decoding and region adaptive hierarchical transform (RAHT)-based attribute decoding.

Both geometry decoding and attribute decoding may have an intra mode and an inter mode as a decoding mode.

Geometry decoding is neural network-based decoding, and a neural network weight may be obtained according to model identifier information before a geometry decoding process is executed. Here, model identifier information may be information explicitly signaled from a bitstream, information pre-defined in a device or information implicitly determined by another information.

For octree level i=1, eight binary occupancy values may be decoded in a raw coding unit consisting of a single byte. Eight voxels may be arranged in a raster scanning order. The bit of a byte in a raw coding unit may be indexed from the most significant bit (MSB) to the least significant bit (LSB). Each bit may represent the occupancy status of a corresponding voxel. At this level, residual feature

$${\hat{F}}_{r}^{1} ,$$

Tensor<0, 8> may be set as a constant dummy feature in which all elements are 1.

For intra point cloud geometry decoding, based on the geometry bitstream of a point cloud, the geometry of a decoded point cloud may be constructed in a learning-based geometry decoding unit. Intra point cloud geometry decoding may be executed per coded octree level, starting from octree level i=2.

For inter point cloud geometry decoding, based on a motion bitstream and a reference frame, geometry predictor information may be generated in a learning-based motion decoding unit. Geometry predictor information may be shared to the learning-based geometry decoding unit of intra decoding as an additional input to construct the geometry of a decoded point cloud in the learning-based geometry decoding unit of intra decoding. Inter point cloud geometry decoding may be executed per coded octree level, starting from octree level i=2.

For intra point cloud attribute decoding, based on an attribute bitstream and decoded point cloud geometry, a decoded point cloud attribute may be constructed in an RAHT-based attribute decoding unit.

For inter point cloud attribute decoding, based on decoded point cloud geometry and an attribute reference frame, attribute predictor information may be generated in a recoloring unit. Attribute predictor information may be shared to the RAHT-based attribute decoding unit of intra decoding as an additional input to construct a decoded point cloud attribute in the RAHT-based attribute decoding unit of intra decoding.

A point cloud geometry intra decoding process (=a geometry intra decoding process) may be invoked per octree level when a current point cloud slice is determined as a geometry intra mode (e.g., when a unit type is determined as Geometry Intra-Slice). Here, a unit type may be explicitly signaled from a bitstream or may be implicitly determined by another information.

In addition, a geometry intra decoding process may be invoked per octree level when a current octree level is greater than a threshold octree level even when a current point cloud slice is determined as a geometry inter mode (e.g., when a unit type is determined as Geometry Inter-Slice). Here, a threshold octree level may be explicitly signaled from a bitstream or may be implicitly determined by another information.

A geometry intra decoding process may be performed in the learning-based geometry decoding unit of FIG. 4.

The unit type of the present disclosure may include types of geometry intra-slice, geometry inter-slice, attribute intra-slice and attribute inter-slice.

The type of a geometry intra decoding process may include lossless-based decoding and lossy-based decoding.

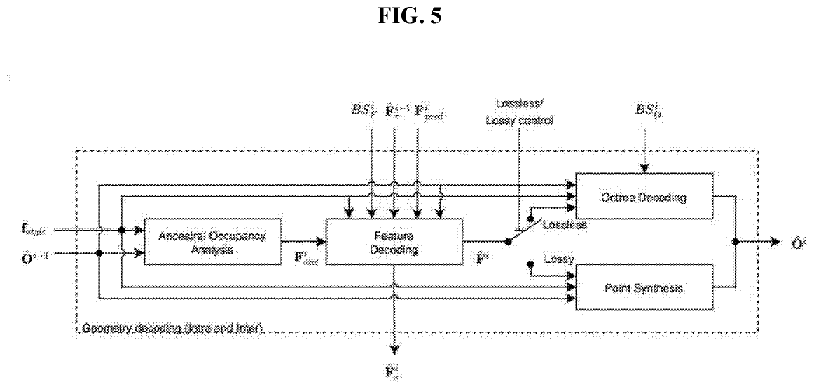

FIG. 5 illustrates an example of lossless decoding and lossy decoding in a geometry decoding process.

A lossy-based decoding process may include 1) an ancestor occupancy analysis step, 2) a feature decoding step and 3) a point synthesis step.

A lossless-based decoding process may include 1) an ancestor occupancy analysis step, 2) a feature decoding step and 4) an octree decoding step.

In other words, in lossy-based and lossless-based decoding processes, 1) an ancestor occupancy analysis step and 2) a feature decoding step may be a common step.

### 1) Ancestor Occupancy Analysis Step

In an ancestor occupancy analysis step, when the occupancy information of the ancestor octree level (i-1, i-2, i-3, i-4) of a current octree level is available, ancestor feature

$${F}_{anc}^{i}$$

may be obtained based on corresponding information.

An ancestor occupancy analysis step may be an initialization step performed before 2) a feature decoding step.

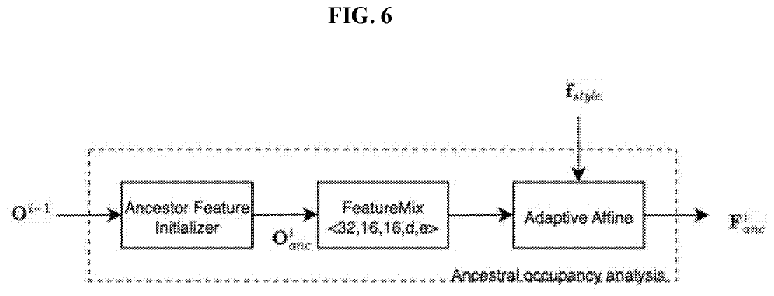

FIG. 6 illustrates an example of an ancestor occupancy analysis step.

An ancestor occupancy analysis step may include an ancestor feature initialization step, a feature mixing step and an adaptive affine step.

An ancestor feature initialization step may obtain ancestor information

$${O}_{anc}^{i} ,$$

which is a 32-dimensional vector, based on the occupancy map Oⁱ⁻¹ of a parent octree level. Here, ancestor information is defined as a connection of [j, p^{j}, o^{j}, v^{j}], and j may be a scalar value representing an octree level index, p may be a 3D vector indicating a 3D position, o may be a 3D vector indicating a binary octant and v may be a scalar value representing a voxel size.

The feature mixing step may be a step for performing a basic neural network-based process for feature aggregation and a channel size transformed from a to c. a and c may be determined through a neural network layer FeatureMix<a, b, c, d, e> in a picture mixing step. As an example, a channel size may be changed from 32 to 16 in the feature mixing step of FIG. 6. All or a part of the parameters used in a feature mixing step may be determined differently based on bit depth-related information.

An adaptive affine step may perform an adaptive affine process that transforms an input feature through learnable affine transform based on style condition f_{style} representing a desired coding motion. An adaptive affine process may be inserted into various processes such as feature extraction, point synthesis, feature encoding, feature decoding, octree encoding, octree decoding, etc. to transform the feature of a corresponding process.

### 2) Feature Decoding Step

In a feature decoding step, based on a feature bitstream for a current octree level

$$B {S}_{F}^{i} ,$$

the ancestor feature of a current octree level

$${F}_{anc}^{i} ,$$

a constant dummy prediction feature F_{pred}, the decoded residual feature of a parent octree level

$${\hat{F}}_{r}^{i - L}$$

and the occupancy map of a parent octree level Ôⁱ⁻¹, the decoded feature of a current octree level \tilde{F}ⁱ and the decoded residual feature of a current octree level

$${\hat{F}}_{r}^{i}$$

may be obtained.

All elements of constant dummy prediction feature F_{pred} may be the same as 1. A constant dummy prediction feature may be used to match geometry feature decoding for intra coding with inter coding.

When there is no feature decoded at a previous level, the decoded residual feature of a parent octree level

$${\hat{F}}_{r}^{i - L}$$

may be set as a dummy feature in which all elements are 1 and used.

A case in which there is no feature decoded at a previous level may include: i) a case in which octree level i=2 is decoded (since a feature is not encoded at octree level i=1) and ii) a case in which the value of a flag indicating that a residual feature is set as a dummy feature for all octree levels for lossless coding is 1.

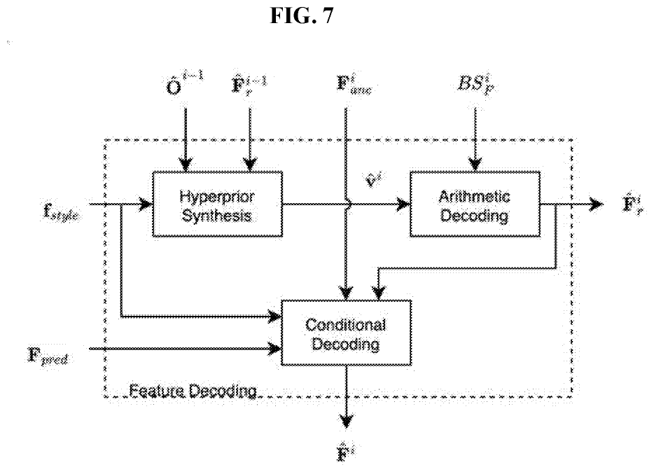

FIG. 7 illustrates an example of a feature decoding step.

A feature decoding step may include a hyper-prior synthesis step, an arithmetic decoding step and a conditional decoding step.

A hyper-prior synthesis step may synthesize a feature variance parameter based on the decoded residual feature of a parent octree level.

An arithmetic decoding step may obtain the decoded residual feature of a current octree level by arithmetic decoding a feature bitstream for a current octree level based on a feature variance parameter obtained in a hyper-prior synthesis step.

A conditional decoding step may conditionally decode the decoded feature of a current octree level by using the ancestor feature and constant dummy prediction feature of a current octree level as a condition and based on the decoded residual feature of a current octree level.

### 3) Point Synthesis Step

In a point synthesis step, based on the decoded feature of a current octree level and the decoded occupancy map of a parent octree level, the (lossy) decoded occupancy map of a current octree level may be obtained.

A point synthesis step may be performed for each octree level constructed for lossy-based decoding.

A point synthesis step may be performed in a different way based on a flag representing whether a MultiLayer Perceptron (MLP) is used.

As an example, when a flag representing whether an MLP is used has the first value, a point synthesis step may be performed by a sparse 3D convolution-based point synthesis method, and when a flag representing whether an MLP is used has the second value, a point synthesis step may be performed by an MLP-based point synthesis method.

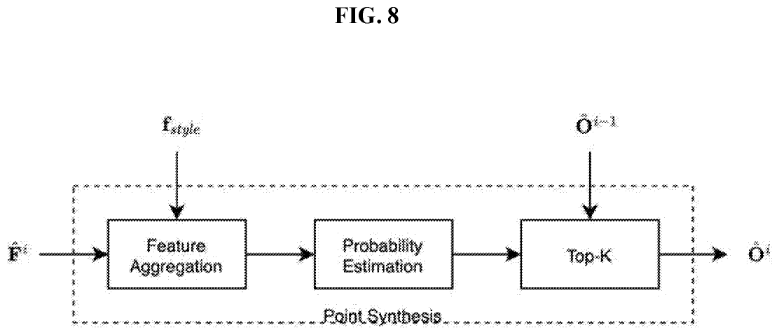

FIG. 8 illustrates an example of a sparse 3D convolution-based point synthesis method.

A sparse 3D convolution-based point synthesis method may have, as an additional input, style condition f_{style} and a parameter representing the number of voxels at a current octree level obtained from a slice geometry header.

A sparse 3D convolution-based point synthesis method may include a feature aggregation step, a probability estimation step and a classification step.

The feature aggregation step of a sparse 3D convolution-based point synthesis method may improve the decoded feature of a current octree level \hat{F}ⁱ and obtain an aggregated and upsampled feature

$${\hat{F}}_{0}^{i}$$

by aggregating and upsampling an improved feature.

The probability estimation step of a sparse 3D convolution-based point synthesis method may use aggregated and upsampled feature

$${\hat{F}}_{0}^{i}$$

as an input and a multilayer perceptron (MLP) network to calculate the prediction occupancy probability of voxels at a current octree level with one channel. In this case, the channel size of a used MLP layer may be determined differently by bit depth-related information.

The classification step of a sparse 3D convolution-based point synthesis method may order all child voxels (current octree levels) having an occupied parent voxel, and then classify K voxels with the highest occupancy probability as being occupied and the remaining voxels as being empty, thereby obtaining the occupancy map of a current octree level.

An MLP-based point synthesis method may include an offset estimation step, a point construction step and a point clipping and pruning step.

The offset estimation step of an MLP-based point synthesis method may transform the decoded feature of a current octree level \hat{F}ⁱ into a feature with 15 channels, and then consider three consecutive channels as one 3D offset vector, thereby generating five 3D offset vectors for each occupied voxel of a parent octree level.

The point construction step of an MLP-based point synthesis method may generate five 3D points of a current octree level by moving each occupied voxel of a parent octree level according to five 3D offset vectors.

The point clipping and pruning step of an MLP-based point synthesis method may obtain the occupancy map of a current octree level by clipping the coordinates of 3D points and pruning a duplicate point based on the bounding box of a point cloud frame.

### 4) Octree Decoding Step

In an octree decoding step, based on the decoded feature of a current octree level \tilde{F}ⁱ, the occupancy map of a parent octree level and the occupancy bitstream of a current octree level, the (lossless) decoded occupancy map of a current octree level may be obtained.

An octree decoding step may be performed for each octree level constructed for lossless-based decoding.

According to bit depth-related information, the mode of an octree decoding step may be determined. The mode of an octree decoding step may include a current level autoregressive mode and a parent level autoregressive mode.

According to a mode, the processes of an octree decoding step may be performed at the resolution of a current octree level or the resolution of a parent octree level.

An octree decoding step may include an initialization step, a feature aggregation step and an occupancy decoding step.

In an initialization step, according to the mode of an octree decoding step, the occupancy map of a parent octree level may be expanded or upsampled to the occupancy map of a current octree level to generate the initial occupancy map of a current octree level

$${O}_{0}^{i} .$$

For a current level autoregressive mode, an initialization step may upsample the occupancy map of a parent octree level to the occupancy map of a current octree level to obtain the initial occupancy map of a current octree level

$${O}_{0}^{i} ,$$

Tensor<i, 1>. The initial occupancy map of a current octree level has 8×voxelCount (the number of occupied voxels of a parent octree level) points, and all child voxels of an occupied parent voxel may be set as 0.

For a parent level autoregressive mode, an initialization step may expand the occupancy map of a parent octree level to the occupancy map of a current octree level to obtain the initial occupancy map of a current octree level

$${O}_{0}^{i} ,$$

Tensor<i−1, 8>. An initialization step may initialize all channels to 0 and repeat the channel of Oⁱ⁻¹ 8 times to generate

$${O}_{0}^{i} .$$

The eight child voxels are mapped to eight channels in which indexes from 0 to 7 are designated, and the order may be (0,0,0), (1,0,0), (0,1,0), (1,1,0), (0,0,1), (1,0,1), (0,1,1), (1,1,1).

In a feature aggregation step, based on the decoded feature of a current octree level \hat{F}ⁱ, an aggregated feature

$${\hat{F}}_{0}^{i}$$

according to a mode may be obtained.

For a current level autoregressive mode, a feature aggregation step may improve the decoded feature of a current octree level \tilde{F}ⁱ and obtain an aggregated feature

$${\hat{F}}_{0}^{i}$$

by aggregating and upsampling an improved feature.

For a parent level autoregressive mode, a feature aggregation step may obtain an aggregated feature

$${\hat{F}}_{0}^{i}$$

by aggregating the decoded feature of a current octree level \hat{F}ⁱ without changing resolution (having the resolution of a parent octree level).

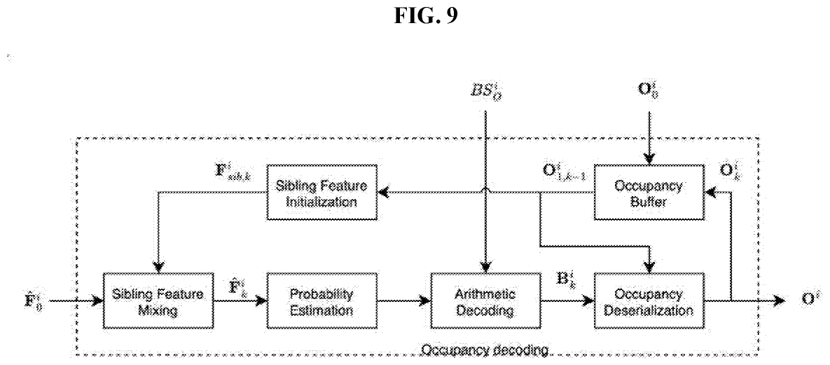

FIG. 9 illustrates an example of an occupancy decoding step.

An occupancy decoding step may be invoked 8 times repeatedly to decode the occupancy map of octree level i. k representing the numbering of repetitions may have a range from 1 to 8. A repetition for eight octants may follow the order of (0,0,0), (1,0,0), (0,1,0), (1,1,0), (0,0,1), (1,0,1), (0,1,1), (1,1,1).

An occupancy decoding step for the kth repetition may be performed by i) an occupancy buffer, ii) a sibling feature initialization unit, iii) a sibling feature mixing unit, iv) a probability estimation unit, v) an arithmetic decoding unit and vi) an occupancy deserialization unit.

### i) Occupancy Buffer

An occupancy buffer may store and provide all sibling occupancy maps decoded in the previous repetition of a current octree level

$${O}_{1 , k - 1}^{i}$$

(from 1 to k−1) to be referenced in the next decoding repetition. In addition, it may also manage a mask which is a decoding mask representing whether a child voxel is decoded. In addition, for the first repetition (k=1), an occupancy buffer may be initialized.

### ii) Sibling Feature Initialization Unit

In a sibling feature initialization unit, an initial sibling feature

$${\hat{F}}_{sib , k}^{i}$$

may be obtained by initializing a feature based on all sibling occupancy maps decoded in a previous repetition

$${O}_{1 , k - 1}^{i} .$$

For a current level autoregressive mode, a sibling feature initialization unit may obtain an initial sibling feature

$${\hat{F}}_{sib , k}^{i}$$

by performing initialization with a five-dimensional vector. In this case, one dimension may represent a scalar value for an octree level, three dimensions may represent a scalar value at a 3D position and one dimension may represent the binary value of a decoding mask map.

For a parent level autoregressive mode, a sibling feature initialization unit may obtain an initial sibling feature

$${\hat{F}}_{sib , k}^{i}$$

by performing initialization in the same way as an input

$${O}_{1 , k - 1}^{i} .$$

iii) Sibling Feature Mixing Unit

In a sibling feature mixing unit, an aggregated feature

$${\hat{F}}_{0}^{i}$$

and an initial sibling feature

$${\hat{F}}_{sib , k}^{i}$$

may be mixed to obtain a mixed feature

$${\hat{F}}_{k}^{i} .$$

The mixing process of a sibling feature mixing unit may be different according to whether a mode is a current level autoregressive mode or a parent level autoregressive mode.

### iv) Probability Estimation Unit

A probability estimation unit may predict the occupancy probability

$${p}_{k}^{i}$$

of voxels of a current octree level for each occupied parent voxel based on a mixed feature

$${\hat{F}}_{k}^{i} .$$

For a current level autoregressive mode, a probability estimation unit may use a multilayer perceptron (MLP) network to predict the occupancy probability

$${p}_{k}^{i}$$

of voxels of a current octree level with one channel. In this case, the channel size of a used MLP layer may be determined differently by bit depth-related information.

For a parent level autoregressive mode, a probability estimation unit may predict the occupancy probability

$${p}_{k}^{i}$$

of voxels or a current octree level by using a convolution layer, an ReLU layer and an Inception ResNet (IRN) layer.

### v) Arithmetic Decoding Unit

An arithmetic decoding unit may obtain the sequence of a binary value

$${B}_{k}^{i}$$

based on an occupancy bitstream and a prediction probability for the current octant of a current octree level.

### vi) Occupancy Deserialization Unit

An occupancy deserialization unit may obtain the occupancy map

$${O}_{k}^{i}$$

of a current repetition by using the decoded occupancy map

$${O}_{k - 1}^{i}$$

and binary sequence

$${B}_{k}^{i}$$

of a previous repetition. An occupancy status may be set as 1 and unoccupied may be set as 0. After all eight repetitions, the decoded occupancy map of a current octree level Oⁱ may be set as a combination of

$${O}_{1}^{i} , {O}_{2}^{i} , … , {O}_{B}^{i} .$$

A point cloud geometry inter decoding process may be invoked per octree level when a current point cloud slice is signaled as a geometry inter mode (=a unit type is signaled as Geometry Inter-Slice) and a current octree level is less than or equal to a threshold octree level.

A point cloud geometry inter decoding process may be performed by a combination of a learning-based geometry decoding unit, a learning-based motion decoding unit and a reference frame unit in FIG. 4.

A point cloud geometry inter decoding process may include a motion decoding process and a main decoding process.

In a motion decoding process, a predictor for a current frame may be obtained based on a motion between a reference frame and a current frame. It may correspond to the learning-based motion decoding unit and a reference frame unit of FIG. 4.

In a main decoding process, geometry decoding may be performed based on a predictor for a current frame. It may correspond to the learning-based geometry decoding unit of FIG. 4.

A global motion compensation process may be invoked as a preprocessing process at every octree level before invoking an inter decoding process.

The input and output of a global motion compensation process may belong to a shifted coding coordinate system.
1) First, the coordinates of each point in a reference point cloud frame Ĝ_{ref} may be transformed based on the point cloud boundary box center (c, c, c). This transform may be performed by Ĝ_{ref}=Ĝ_{ref}−(c,c,c)^{τ}. The position of the boundary box center in a shifted coding coordinate system may be defined as in c=2^{sps_geometry_bit_depth_minus}1.
2) Next, a reference point cloud frame Ĝ_{ref} may be transformed as in Ĝ_{ref}=R×Ĝ_{ref}+T by using rotation matrix R and motion vector T designated by the fps_transform_matrix array of a bitstream.
3) Lastly, a global motion compensation reference frame may be obtained by applying inverse transform to move a reference point cloud frame Ĝ_{ref} back to a shifted coding coordinate system. This inverse transform may be performed by Ĝ_{ref}=Ĝ_{ref}+(c,c,c)^{τ}.

Unless there are special circumstances, when gps_global_motion_flag is the same as 1, the reference point cloud geometry of the present disclosure may be interpreted as a global motion compensation reference point cloud.

A learning-based motion decoding process performed in a learning-based motion decoding unit may be invoked for each octree level for a slice at the start of a point cloud geometry inter decoding process.

A learning-based motion decoding process may generate a predicted feature to support a main decoding process.

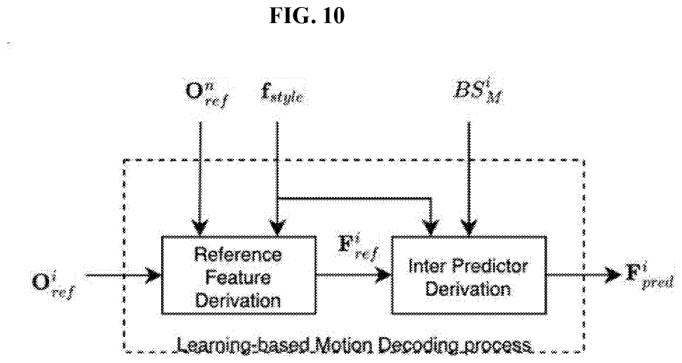

FIG. 10 illustrates an embodiment of a learning-based motion decoding process.

A learning-based motion decoding process may include a reference feature derivation step and an inter predictor derivation step.

A reference feature derivation step may obtain the reference feature of a current octree level by using a style condition and the decoded occupancy map of a current octree level. In addition, when a flag representing whether a MultiLayer Perceptron (MLP) is used is the first value, the occupancy map of a previous octree level may be additionally used to obtain the reference feature of a current octree level.

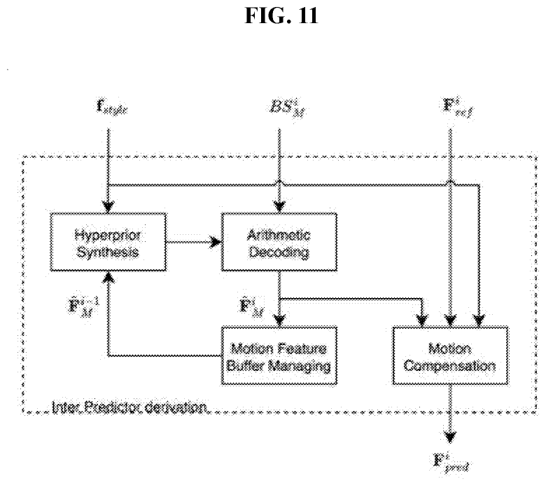

FIG. 11 illustrates an embodiment of an inter predictor derivation step.

An inter predictor derivation step may include a motion feature buffer management step, a hyper-prior synthesis step, an arithmetic decoding step and a motion compensation step.

A motion feature buffer management step may store and provide a decoded motion feature. As an example, a motion feature buffer management process may provide the decoded motion feature of a parent octree level to a hyper-prior synthesis step for a current octree level.

A hyper-prior synthesis step may synthesize a feature variance parameter by using the motion feature of a parent octree level. A hyper-prior synthesis step may operate in the same manner as a hyper-prior synthesis step described above. However, an input may be the decoded motion feature of a parent octree level instead of the decoded residual feature of a parent octree level.

An arithmetic decoding step may operate in the same manner as an arithmetic decoding step described above. However, an input bitstream may be substituted with a motion bitstream. In other words, an arithmetic decoding step may obtain the decoded motion feature of a current octree level by arithmetic decoding a motion bitstream based on a feature variance parameter obtained in a hyper-prior synthesis step.

In a motion compensation step, the prediction feature

$${F}_{pred}^{i}$$

of a current octree level may be obtained based on the decoded motion feature of a current octree level, the reference feature of a current octree level and a style condition.

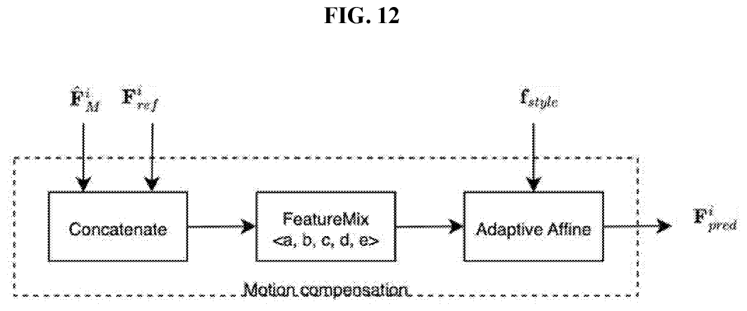

FIG. 12 illustrates an example of a motion compensation step.

A main decoding process may be invoked at each octree level of a slice after a learning-based motion decoding process is completed.

A main decoding process is performed in the learning-based geometry decoding unit of FIG. 4, and a corresponding unit may be a neural network shared with a geometry intra decoding process.

Similar to a geometry intra decoding process, the type of a main decoding process may include lossless-based decoding and lossy-based decoding.

Compared to a geometry intra decoding process, a difference in a main decoding process may be using a prediction feature generated in a learning-based motion decoding process instead of a dummy feature.

A lossy-based decoding process may include 1) an ancestor occupancy analysis step, 2) a feature decoding step and 3) a point synthesis step.

A lossless-based decoding process may include 1) an ancestor occupancy analysis step, 2) a feature decoding step and 4) an octree decoding step.

In other words, in lossy-based and lossless-based decoding processes, 1) an ancestor occupancy analysis step and 2) a feature decoding step may be a common step.

### 1) Ancestor Occupancy Analysis Step

In an ancestor occupancy analysis step, when the occupancy information of the ancestor octree level (i-1, i-2, i-3, i-4) of a current octree level is available, an ancestor feature

$${F}_{anc}^{i}$$

may be obtained based on corresponding information.

In an ancestor occupancy analysis step, when the occupancy information of the ancestor octree level (i-1, i-2, i-3, i-4) of a current octree level is available, an ancestor feature

may be obtained based on corresponding information.

An ancestor occupancy analysis step may include an ancestor feature initialization step, a feature mixing step and an adaptive affine step. Since the specific details of each step of an ancestor occupancy analysis step are described above, they are omitted below.

### 2) Feature Decoding Step

Based on a feature bitstream for a current octree level

$${BS}_{F}^{i} ,$$

the ancestor feature of a current octree level

$${F}_{anc}^{i}$$

in a feature decoding step, the prediction feature of a current octree level

$${F}_{pred}^{i} ,$$

the decoded residual feature of a parent octree level

$${\hat{F}}_{r}^{i - 1}$$

and the occupancy map of a parent octree level Ôⁱ⁻¹, the decoded feature of a current octree level \hat{F}ⁱ and the decoded residual feature of a current octree level

$${\hat{F}}_{r}^{i}$$

may be obtained.

### 3) Point Synthesis Step

In a point synthesis step, based on the decoded feature of a current octree level \hat{F}ⁱ and the occupancy map of a parent octree level, the (lossy) decoded occupancy map of a current octree level may be obtained.

A point synthesis step may be performed for each octree level constructed for lossy-based decoding.

A point synthesis step may be performed in a different way based on a flag representing whether a MultiLayer Perceptron (MLP) is used.

As an example, when a flag representing whether an MLP is used has the first value, a sparse 3D convolution-based point synthesis method may be performed, and when a flag representing whether an MLP is used has the second value, an MLP-based point synthesis method may be performed. Since the specific details of a point synthesis step are described above, they are omitted below.

### 4) Octree Decoding Step

In an octree decoding step, based on the decoded feature of a current octree level \tilde{F}ⁱ and the occupancy map of a parent octree level, the (lossless) decoded occupancy map of a current octree level may be obtained.

An octree decoding step may be performed for each octree level constructed for lossless-based decoding.

According to bit depth-related information, the mode of an octree decoding step may be determined. The mode of an octree decoding step may include a current level autoregressive mode and a parent level autoregressive mode.

Since the specific details of an octree decoding step are described above, they are omitted below.

Region adaptive hierarchical transform (RAHT)-based attribute decoding may include intra point cloud attribute decoding and inter point cloud attribute decoding.

For intra point cloud attribute decoding, based on an attribute bitstream and decoded point cloud geometry, a decoded point cloud attribute may be obtained in an RAHT-based attribute decoding unit.

For inter point cloud attribute decoding, based on decoded point cloud geometry and an attribute reference frame, attribute predictor information may be generated in an attribute predictor generation unit. As an example, when an attribute is a color, attribute predictor information may be generated in a recoloring unit. Attribute predictor information may be shared to the RAHT-based attribute decoding unit of intra decoding as an additional input to obtain a decoded point cloud attribute in the RAHT-based attribute decoding unit of intra decoding.

After a point cloud geometry slice is decoded, whether to perform an inverse scaling process may be determined based on a coordinate transform flag representing that point cloud geometry is transformed from a world coordinate system to a coding coordinate system and scaling ratio information representing the amount of scaling from a shifted coding coordinate system to a scaled coding coordinate system.

As an embodiment, an inverse scaling process may be performed when a coordinate transform flag is 1 and the amount of scaling of scaling ratio information is less than 1.

In an inverse scaling process, based on decoded point cloud geometry Ĝ which is a set of 3D point positions of a coding coordinate system and a scaling coefficient specified by scaling ratio information, unscaled point cloud geometry which is a set of 3D point positions of a shifted coding coordinate system may be obtained.

In addition, based on inverse scaling type information representing the type of an inverse scaling process, an inverse scaling process may be performed by a simple inverse scaling process or an improved inverse scaling process.

An inverse scaling process may be invoked when a point cloud geometry slice is decoded and a coordinate transform flag is a value equal to 1. In addition, when scaling ratio information represents a value less than 1, an inverse transform process may be additionally invoked after an inverse scaling process is completed.

An inverse transform process may move the point cloud geometry of a shifted coding coordinate system back to a world coordinate system.

When assembly process-related information represents that a point cloud frame is partitioned into slices and coded individually, an assembly process is invoked after all point cloud slices are decoded, and may obtain a point cloud frame by assembling all decoded point cloud slices.

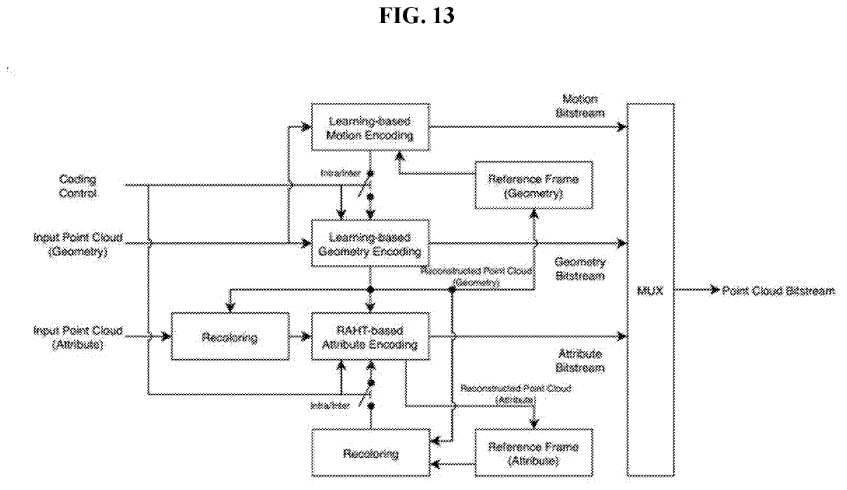

FIG. 13 illustrates an example of the overall encoding process.

The encoding process of the present disclosure may include learning-based point cloud geometry encoding and region adaptive hierarchical transform (RAHT)-based attribute encoding.

Both geometry encoding and attribute encoding may have an intra mode and an inter mode as an encoding mode.

Geometry encoding is neural network-based encoding, and a neural network weight may be determined before a geometry encoding process is executed. Model identifier information representing a neural network weight may be encoded directly or indirectly into a bitstream. Alternatively, a neural network weight may be a pre-defined value between an encoder and a decoder.

For octree level i=1, eight binary occupancy values may be encoded in a raw coding unit consisting of a single byte. Eight voxels may be arranged in a raster scanning order. The bit of a byte in a raw coding unit may be indexed from the most significant bit (MSB) to the least significant bit (LSB). Each bit may represent the occupancy status of a corresponding voxel. At this level, a residual feature, Tensor<0, 8> may be set as a constant dummy feature in which all elements are 1.

For intra point cloud geometry encoding, the geometry of an encoded point cloud may be constructed in a learning-based geometry encoding unit and encoded in a bitstream. Intra point cloud geometry encoding may be executed per each octree level, starting from octree level i=2.

For inter point cloud geometry encoding, geometry predictor information may be generated in a learning-based motion encoding unit and a motion bitstream may be encoded based on geometry predictor information and a reference frame. Geometry predictor information may be shared to the learning-based geometry encoding unit of intra encoding as an additional input to construct the geometry of an encoded point cloud in the learning-based geometry encoding unit of intra encoding. Inter point cloud geometry encoding may be executed per each octree level, starting from octree level i=2.

For intra point cloud attribute encoding, an encoded point cloud attribute may be constructed in an RAHT-based attribute encoding unit and an attribute bitstream may be encoded based on an encoded point cloud attribute and encoded point cloud geometry.

For inter point cloud attribute encoding, based on encoded point cloud geometry and an attribute reference frame, attribute predictor information may be generated in a recoloring unit. Attribute predictor information may be shared to the RAHT-based attribute encoding unit of intra encoding as an additional input to construct an encoded point cloud attribute in the RAHT-based attribute encoding unit of intra encoding and encode an attribute bitstream based on an encoded point cloud attribute.

The specific details of an encoding process may correspond to the specific details of a decoding process.

A (geometry) transform process may be invoked as a preprocessing step. A transform process may transform a point cloud in a world coordinate system into a shifted coding coordinate system. Later, a decoder may perform a process for transforming an output back into a world coordinate system.

After a transform process is completed, whether to perform a (geometry) scaling process may be determined based on a coordinate transform flag representing that point cloud geometry is transformed from a world coordinate system to a coding coordinate system and scaling ratio information representing the amount of scaling from a shifted coding coordinate system to a scaled coding coordinate system.

As an embodiment, a scaling process may be performed when a coordinate transform flag is 1 and the amount of scaling of scaling ratio information is less than 1.

In a scaling process, based on point cloud geometry Ĝ which is a set of 3D point positions of a shifted coding coordinate system and a scaling coefficient specified by scaling ratio information, the scaled point cloud geometry of a shifted coding coordinate system may be obtained.

A point cloud geometry intra encoding process (=a geometry intra encoding process) may be invoked per octree level when a current point cloud slice is determined as a geometry intra mode (e.g., when a unit type is determined as Geometry Intra-Slice).

In addition, a geometry intra encoding process may be invoked per octree level when a current octree level is greater than a threshold octree level even when a current point cloud slice is determined as a geometry inter mode (e.g., when a unit type is determined as Geometry Inter-Slice). Here, a threshold octree level may be encoded directly or indirectly into a bitstream.

A geometry intra encoding process may be performed in the learning-based geometry encoding unit of FIG. 13.

The unit type of the present disclosure may include types of geometry intra-slice, geometry inter-slice, attribute intra-slice and attribute inter-slice.

The type of a geometry intra encoding process may include lossless-based encoding and lossy-based encoding.

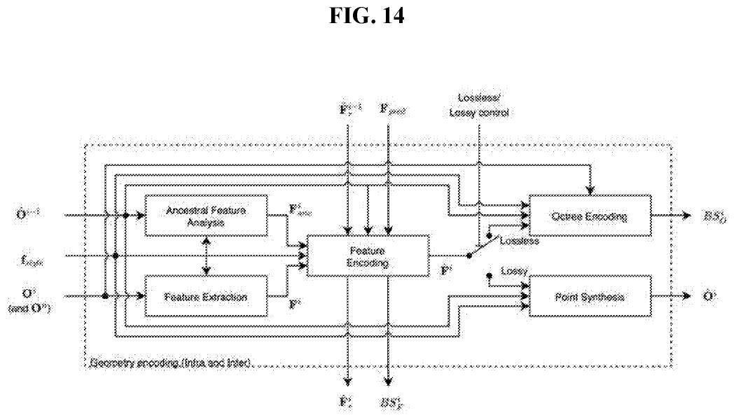

FIG. 14 illustrates an example of lossless encoding and lossy encoding in a geometry encoding process.

A lossy-based encoding process may include 1) an ancestor occupancy analysis step, 2) a feature extraction step, 3) a feature encoding step and 4) a point synthesis step.

A lossless-based encoding process may include 1) an ancestor occupancy analysis step, 2) a feature extraction step, 3) a feature encoding step and 5) an octree encoding step.

In other words, in lossy-based and lossless-based encoding processes, 1) an ancestor occupancy analysis step, 2) a feature extraction step and 3) a feature encoding step may be a common step.

### 1) Ancestor Occupancy Analysis Step

In an ancestor occupancy analysis step, when the occupancy information of the ancestor octree level (i-1, i-2, i-3, i-4) of a current octree level is available, ancestor feature

$${F}_{anc}^{i}$$

may be obtained based on corresponding information.

An ancestor occupancy analysis step may be an initialization step performed before 3) a feature encoding step.

An ancestor occupancy analysis step may include an ancestor feature initialization step, a feature mixing step and an adaptive affine step. Since the specific details of each step are the same as those in a geometry decoding process, they are omitted below.

### 2) Feature Extraction Step

Based on the voxel occupancy map Oⁱ of the current octree level of an input point cloud and a style condition f_{style}, a feature Fⁱ representing the local geometry information of the current octree level of an input point cloud may be obtained.

A feature extraction step may be performed in a different way based on a flag representing whether a MultiLayer Perceptron (MLP) is used.

As an example, when a flag representing whether an MLP is used has the first value, the voxel occupancy map Oⁿ of the parent octree level of an input point cloud may be provided as an additional input.

As an example, when a flag representing whether an MLP is used has the second value, a sparse 3D convolution-based feature extraction method may be performed.

### 3) Feature Encoding Step

In a feature encoding step, based on a feature Fⁱ representing geometry information about a current octree level, the ancestor feature of a current octree level

$${F}_{anc}^{i} ,$$

a constant dummy prediction feature F_{pred} and the decoded residual feature of a parent octree level

$${\hat{F}}_{r}^{i - 1} ,$$

a feature bitstream

$${BS}_{F}^{i}$$

for a current octree level, the decoded feature of a current octree level \hat{F}ⁱ and the decoded residual feature of a current octree level

$${\hat{F}}_{r}^{i}$$

may be obtained.

All elements of constant dummy prediction feature F_{pred} may be the same as 1. A constant dummy prediction feature may be used to match geometry feature encoding for intra coding with inter coding.

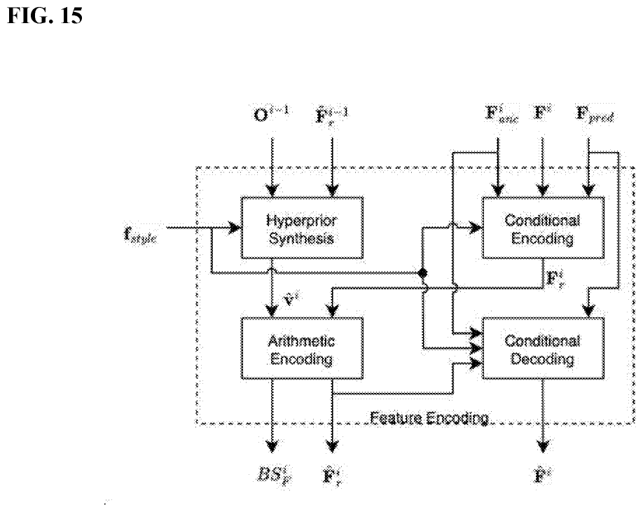

FIG. 15 illustrates an example of a feature encoding step.

A feature encoding step may include a hyper-prior synthesis step, a conditional encoding step, an arithmetic encoding step and a conditional decoding step.

A hyper-prior synthesis step may synthesize a feature variance parameter based on the decoded residual feature of a parent octree level.

A conditional encoding step may conditionally encode the feature of a current octree level by using the ancestor feature and constant dummy prediction feature of a current octree level as a condition and based on the residual feature of a current octree level.

An arithmetic encoding step may obtain the decoded residual feature and feature bitstream of a current octree level based on a feature variance parameter obtained in a hyper-prior synthesis step and the residual feature of a current octree level.

A conditional decoding step may conditionally decode the decoded feature of a current octree level by using the ancestor feature and constant dummy prediction feature of a current octree level as a condition and based on the decoded residual feature of a current octree level.

### 4) Point Synthesis Step

In a point synthesis step, based on the decoded feature of a current octree level \hat{F}ᵢ and the occupancy map of a parent octree level, the (lossy) decoded occupancy map of a current octree level may be obtained.

A point synthesis step may be performed in a different way based on whether a MultiLayer Perceptron (MLP) is used.

As an example, when an MLP is used, a sparse 3D convolution-based point synthesis method may be performed, and when an MLP is not used, an MLP-based point synthesis method may be performed.

Information representing whether an MLP is used may be encoded in a bitstream.

Since the specific details of a sparse 3D convolution-based point synthesis method and an MLP-based point synthesis method are described above, they are omitted below.

### 5) Octree Encoding Step

In an octree encoding step, based on the decoded feature of a current octree level \hat{F}ⁱ, the occupancy map of a parent octree level and the occupancy map of a current octree level, an occupancy bitstream for a current octree level

$$BS \text{?}$$

$$\text{?} \text{indicates text missing or illegible when filed}$$

may be obtained.

An octree encoding step may be performed for each octree level constructed for lossless-based encoding.

According to bit depth-related information, the mode of an octree encoding step may be determined. The mode of an octree encoding step may include a current level autoregressive mode and a parent level autoregressive mode.

According to a mode, the intermediate processes of an octree encoding step may be performed at the resolution of a current octree level or the resolution of a parent octree level.

An octree encoding step may include an initialization step, a feature aggregation step and an occupancy encoding step.

In an initialization step, according to the mode of an octree encoding step, the occupancy map of a parent octree level may be expanded or upsampled to the occupancy map of a current octree level to generate the initial occupancy map of a current octree level

For a current level autoregressive mode, an initialization step may upsample the occupancy map of a parent octree level to the occupancy map of a current octree level to obtain the initial occupancy map of a current octree level

$${O}_{0}^{i} ,$$

Tensor<i, 1>. The initial occupancy map of a current octree level has 8×voxelCount (the number of occupied voxels of a parent octree level) points, and all child voxels of an occupied parent voxel may be set as 0.

For a parent level autoregressive mode, an initialization step may expand the occupancy map of a parent octree level to the occupancy map of a current octree level to obtain the initial occupancy map of a current octree level

$${O}_{0}^{i} ,$$

Tensor<i−1, 8>. An initialization step may initialize all channels to 0 and repeat the channel of Oⁱ⁻¹ 8 times to generate

$${O}_{0}^{i} .$$

The eight child voxels are mapped to eight channels in which indexes from 0 to 7 are designated, and the order may be (0,0,0), (1,0,0), (0,1,0), (1,1,0), (0,0,1), (1,0,1), (0,1,1), (1,1,1).

In a feature aggregation step, the decoded feature of a current octree level \hat{F}ⁱ may be improved to obtain an aggregated feature

$${\hat{F}}_{0}^{i}$$

according to a mode.

For a current level autoregressive mode, a feature aggregation step may improve the decoded feature of a current octree level \hat{F}ⁱ and obtain an aggregated feature

$${\hat{F}}_{0}^{i}$$

by aggregating and upsampling an improved feature.

For a parent level autoregressive mode, a feature aggregation step may obtain an aggregated feature

$${\hat{F}}_{0}^{i}$$

by aggregating the decoded feature of a current octree level \hat{F}ⁱ without changing resolution (having the resolution of a parent octree level).

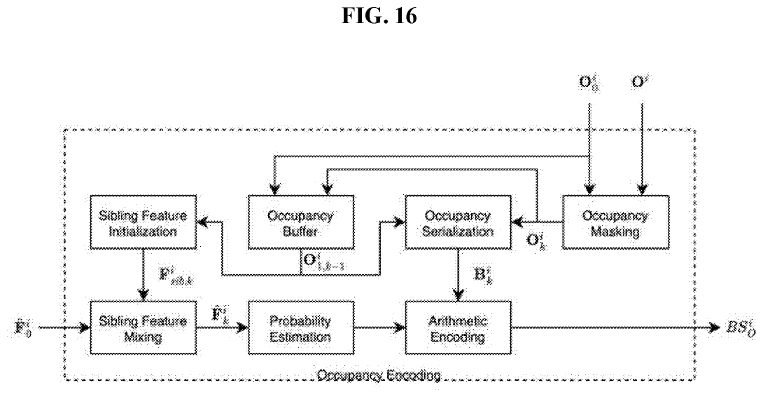

FIG. 16 illustrates an example of an occupancy encoding step.

An occupancy encoding step may be invoked 8 times repeatedly to encode the occupancy map of octree level i. k representing the numbering of repetitions may have a range from 1 to 8. A repetition for eight octants may follow the order of (0,0,0), (1,0,0), (0, 1,0), (1,1,0), (0,0,1), (1,0,1), (0,1,1), (1,1,1).

An occupancy encoding step for the kth repetition may be performed by i) an occupancy buffer, ii) a sibling feature initialization unit, iii) a sibling feature mixing unit, iv) a probability estimation unit, v) an occupancy masking unit, vi) an occupancy serialization unit and vii) an arithmetic encoding unit.

### i) Occupancy Buffer

An occupancy buffer may store and provide all sibling occupancy maps decoded in the previous repetition of a current octree level

$${O}_{1 , k - 1}^{i}$$

(from 1 to k−1) to be referenced in the next decoding repetition. In addition, it may also manage a mask which is a decoding mask representing whether a child voxel is decoded. In addition, for the first repetition (k=1), an occupancy buffer may be initialized.

### ii) Sibling Feature Initialization Unit

In a sibling feature initialization unit, an initial sibling feature

$${\hat{F}}_{sib , k}^{i}$$

may be obtained by initializing a feature based on all sibling occupancy maps decoded in a previous repetition

$${O}_{1 , k - 1}^{i} .$$

For a current level autoregressive mode, a sibling feature initialization unit may obtain an initial sibling feature

$${\hat{F}}_{sib , k}^{i}$$

by performing initialization with a five-dimensional vector. In this case, one dimension may represent a scalar value for an octree level, three dimensions may represent a scalar value at a 3D position and one dimension may represent the binary value of a decoding mask map.

For a parent level autoregressive mode, a sibling feature initialization unit may obtain an initial sibling feature

$${\hat{F}}_{sib , k}^{i}$$

by performing initialization in the same way as an input

$${O}_{1 , k - 1}^{i} .$$

iii) Sibling Feature Mixing Unit

In a sibling feature mixing unit, an aggregated feature

$${\hat{F}}_{0}^{i}$$

and an initial sibling feature

$${\hat{F}}_{sib , k}^{i}$$

may be mixed to obtain a mixed feature

$${\hat{F}}_{k}^{i} .$$

The mixing process of a sibling feature mixing unit may be different according to whether a mode is a current level autoregressive mode or a parent level autoregressive mode.

### iv) Probability Estimation Unit

In a probability estimation unit, based on a mixed feature

$${\hat{F}}_{k}^{i} ,$$

the occupancy probability

$${p}_{k}^{i}$$

of voxels of a current octree level may be predicted for each occupied parent voxel.

For a current level autoregressive mode, a probability estimation unit may use a multilayer perceptron (MLP) network to predict the occupancy probability

$${p}_{k}^{i}$$

of voxels of a current octree level with one channel. In this case, the channel size of a used MLP layer may be determined differently by bit depth-related information.

For a parent level autoregressive mode, a probability estimation unit may predict the occupancy probability

$${p}_{k}^{i}$$

of voxels of a current octree level by using a convolution layer, an ReLU layer and an Inception ResNet (IRN) layer.

### v) Occupancy Masking Unit

The kth occupancy map

$${O}_{k}^{i}$$

of a current repetition may be obtained based on the upsampled occupancy map

$${O}_{0}^{i}$$

or a current octree level based on a parent octree level.

### vi) Occupancy Serialization Unit

In an occupancy serialization unit, a binary sequence

$${B}_{k}^{i}$$

may be obtained based on the occupancy map

$${O}_{k}^{i}$$

of a current repetition.
vii) Arithmetic Encoding Unit

In an arithmetic encoding unit, an occupancy bitstream may be generated by encoding the sequence of a binary value

$${B}_{k}^{i}$$

by using a prediction probability for the current octant of a current octree level.

A point cloud geometry inter encoding process may be invoked per octree level when a current point cloud slice is determined as a geometry inter mode (=a unit type is determined as Geometry Inter-Slice) and a current octree level is less than or equal to a threshold octree level.

A point cloud geometry inter encoding process may be performed by a combination of a learning-based geometry encoding unit, a learning-based motion encoding unit and a reference frame unit in FIG. 13.

A point cloud geometry inter encoding process may include a motion encoding process and a main encoding process.

In a motion encoding process, a motion between a reference frame and a current frame may be estimated and a predictor for a current frame may be obtained. It may correspond to the learning-based motion encoding unit and a reference frame unit of FIG. 13.

In a main encoding process, geometry encoding may be performed based on a predictor for a current frame. It may correspond to the learning-based geometry encoding unit of FIG. 13.

A global motion evaluation and compensation process may be invoked as a preprocessing process at every octree level before invoking an inter encoding process.

The input and output of a global motion evaluation and compensation process may belong to a shifted coding coordinate system.
1) First, the coordinates of each point in a current point cloud frame G_{curr} and a reference point cloud frame G_{ref} may be transformed based on the point cloud boundary box center (c, c, c). This transform may be performed by G_{curr}=G_{curr}−(c,c,c)^{τ} and G_{ref}=G_{ref}−(c,c,c)^{τ}.

The position of the boundary box center in a shifted coding coordinate system may be defined as in c=2^{sps_geometry_bit_depth_minus1}.
2) Next, a global motion expressed as rotation matrix R and motion vector T may be determined, and a reference point cloud frame G_{ref} may be transformed as in G_{ref}=R×G_{ref}+T by using rotation matrix R and motion vector T.
3) Lastly, a global motion compensation reference frame may be obtained by applying transform to move a reference point cloud frame G_{ref} back to a shifted coding coordinate system. This transform may be performed by G_{ref}=G_{ref}+(c,c,c)^{τ}.

A learning-based motion encoding process performed in a learning-based motion encoding unit may be invoked for each octree level for a slice at the start of a point cloud geometry inter decoding process.

A learning-based motion encoding process may generate a predicted feature to support a main encoding process.

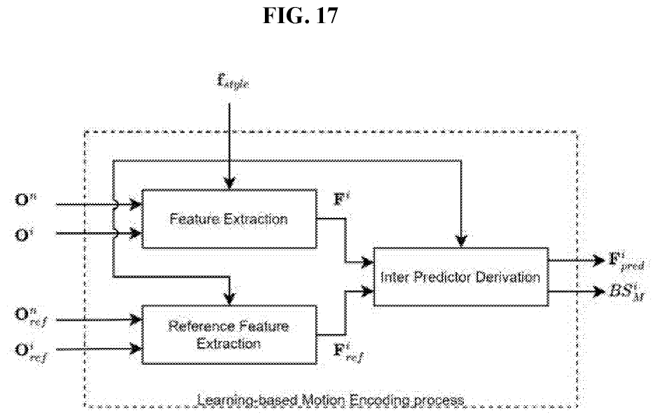

FIG. 17 illustrates an embodiment of a learning-based motion encoding process.

A learning-based motion encoding process may include a feature derivation step, a reference feature derivation step and an inter predictor derivation step.

A feature derivation step may obtain the feature of a current octree level by using a style condition and the occupancy map of a current octree level. In addition, when a MultiLayer Perceptron (MLP) is used, the current occupancy map of a previous octree level may be additionally used to obtain the feature of a current octree level.

A reference feature derivation step may obtain the reference feature of a current octree level based on a style condition and the reference occupancy map of a reference point cloud for a current octree level. In addition, when a MultiLayer Perceptron (MLP) is used, the reference occupancy map of the reference point cloud of a previous octree level may be additionally used to obtain the reference feature of a current octree level.

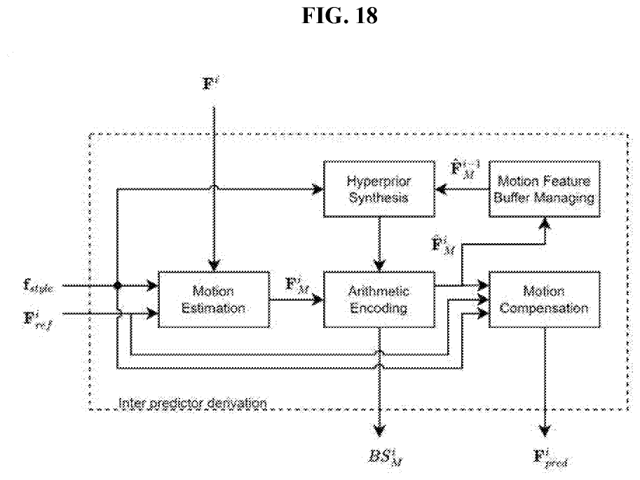

FIG. 18 illustrates an embodiment of an inter predictor derivation step.

An inter predictor derivation step may include a motion feature buffer management step, a hyper-prior synthesis step, a motion evaluation step, an arithmetic encoding step and a motion compensation step.

A motion feature buffer management step may store and provide a decoded motion feature. As an example, a motion feature buffer management process may provide the decoded motion feature of a parent octree level to a hyper-prior synthesis step for a current octree level.

A hyper-prior synthesis step may synthesize a feature variance parameter by using the motion feature of a parent octree level. A hyper-prior synthesis step may operate in the same manner as a hyper-prior synthesis step described above. However, an input may be the decoded motion feature of a parent octree level instead of the decoded residual feature of a parent octree level.

In a motion evaluation step, the motion feature of a current octree level may be obtained based on the feature of the current point cloud of a current octree level, the reference feature of the reference point cloud of a current octree level and a style condition.

An arithmetic encoding step may operate in the same manner as an arithmetic encoding step described above. However, the residual feature of an input current octree level may be substituted with the motion feature of a current octree level. In other words, an arithmetic encoding step may obtain a motion bitstream by arithmetic encoding the motion feature of a current octree level based on a feature variance parameter obtained in a hyper-prior synthesis step.

In a motion compensation step, the prediction feature

$${F}_{pred}^{i}$$

of a current octree level may be obtained based on the decoded motion feature of a current octree level, the reference feature of a current octree level and a style condition.

A main encoding process may be invoked at each octree level of a slice after a learning-based motion encoding process is completed.

A main encoding process is performed in the learning-based geometry encoding unit of FIG. 13, and a corresponding unit may be a neural network shared with a geometry intra encoding process.

Similar to a geometry intra encoding process, the type of a main encoding process may include lossless-based encoding and lossy-based encoding.

Compared to a geometry intra encoding process, a difference in a main encoding process may be using a prediction feature generated in a learning-based motion encoding process instead of a dummy feature.

A lossy-based encoding process may include 1) an ancestor occupancy analysis step, 2) a feature extraction step, 3) a feature encoding step and 4) a point synthesis step.

A lossless-based encoding process may include 1) an ancestor occupancy analysis step, 2) a feature extraction step, 3) a feature encoding step and 5) an octree encoding step.

In other words, in lossy-based and lossless-based encoding processes, 1) an ancestor occupancy analysis step, 2) a feature extraction step and 3) a feature encoding step may be a common step.

### 1) Ancestor Occupancy Analysis Step

In an ancestor occupancy analysis step, when the occupancy information of the ancestor octree level (i-1, i-2, i-3, i-4) of a current octree level is available, ancestor feature

$${F}_{anc}^{i}$$

may be obtained based on corresponding information.

An ancestor occupancy analysis step may be an initialization step performed before 3) a feature encoding step.

An ancestor occupancy analysis step may include an ancestor feature initialization step, a feature mixing step and an adaptive affine step. Since the specific details of each step are the same as those in a geometry decoding process, they are omitted below.

### 2) Feature Extraction Step

Based on the voxel occupancy map Oⁱ of the current octree level of an input point cloud and a style condition f_{style}, a feature Fⁱ representing the local geometry information of the current octree level of an input point cloud may be obtained.

A feature extraction step may be performed in a different way based on whether a MultiLayer Perceptron (MLP) is used.

As an example, when an MLP is used, the voxel occupancy map Oⁿ of the parent octree level of an input point cloud may be provided as an additional input.

As an example, when an MLP is not used, a sparse 3D convolution-based feature extraction method may be performed.

### 3) Feature Encoding Step

In a feature encoding step, based on a feature Fⁱ representing geometry information about a current octree level, the ancestor feature of a current octree level

$${F}_{anc}^{i} ,$$

the prediction feature of a current octree level

$${F}_{pred}^{i}$$

and the decoded residual feature of a parent octree level

$${\hat{F}}_{r}^{i - 1} ,$$

a feature bitstream

$${BS}_{F}^{i}$$

for a current octree level, the decoded feature of a current octree level \hat{F}ⁱ and the decoded residual feature of a current octree level

$${\hat{F}}_{r}^{i}$$

may be obtained.

### 4) Point Synthesis Step

In a point synthesis step, based on the decoded feature of a current octree level \hat{F}ⁱ and the occupancy map of a parent octree level, the (lossy) decoded occupancy map of a current octree level may be obtained.

A point synthesis step may be performed in a different way based on whether a MultiLayer Perceptron (MLP) is used.

As an example, when an MLP is used, a sparse 3D convolution-based point synthesis method may be performed, and when an MLP is not used, an MLP-based point synthesis method may be performed. Since the specific details of each method are described above, they are omitted below.

### 5) Octree Encoding Step

In an octree encoding step, based on the decoded feature of a current octree level \hat{F}ⁱ, the occupancy map of a parent octree level and the occupancy map of a current octree level, an occupancy bitstream for a current octree level

$${BS}_{O}^{i}$$

may be obtained.

An octree encoding step may be performed for each octree level constructed for lossless-based encoding.

According to bit depth-related information, the mode of an octree encoding step may be determined. The mode of an octree encoding step may include a current level autoregressive mode and a parent level autoregressive mode.

According to a mode, the intermediate processes of an octree encoding step may be performed at the resolution of a current octree level or the resolution of a parent octree level.

An octree encoding step may include an initialization step, a feature aggregation step and an occupancy encoding step.

Since the specific details of an octree encoding step are described above, they are omitted below.

Region adaptive hierarchical transform (RAHT)-based attribute encoding may include intra point cloud attribute encoding and inter point cloud attribute encoding.

For intra point cloud attribute encoding, based on an input point cloud attribute and encoded point cloud geometry, an attribute bitstream may be encoded in an RAHT-based attribute encoding unit.

For inter point cloud attribute encoding, based on restored point cloud geometry and an attribute reference frame, attribute predictor information may be generated in an attribute predictor generation unit. As an example, when an attribute is a color, attribute predictor information may be generated in a recoloring unit. Attribute predictor information may be shared to the RAHT-based attribute encoding unit of intra encoding as an additional input to obtain an attribute bitstream in the RAHT-based attribute encoding unit of intra encoding.

As an embodiment, a method for encoding/decoding a latent representation in a deep learning-based AI compression model may be considered. The AI compression model includes an encoder and a decoder, and may convert input data into a latent representation, compress and store or transmit it, and then restore the original data through decoding.

As an embodiment, a latent representation encoding/decoding process may include the following procedure.

First, input data may be converted into a low-dimensional latent representation through a deep learning-based encoder. Subsequently, a latent representation may be compressed through entropy encoding, and entropy encoding may include a method such as arithmetic coding or Huffman coding. A compressed bitstream may be stored or transmitted, and during a decoding process, a latent representation may be restored through entropy decoding, and then the original data may be reconstructed through a decoder.

As an embodiment, a latent representation may be composed of a plurality of channels, and each channel may have a multidimensional data form including a spatial axis and a channel axis. In this case, some channels do not include meaningful information according to the characteristics of input data, and may be an inactive channel where all element values of a corresponding channel are set as 0.

However, in a latent representation encoding/decoding method according to an embodiment, all channels including an inactive channel may be included in an encoding target. In other words, entropy encoding may be performed even on a channel where information is not present and accordingly, an unnecessary bit may occur.

In addition, a method for processing all channels identically may increase an unnecessary computation during encoding and decoding processes, which may increase overall computational complexity and degrade processing speed. In particular, in a real-time processing environment or an environment with limited computational resources, this computational burden may be a major cause of performance degradation.

Furthermore, a method according to an embodiment processes all channels identically without considering the characteristics of input data or importance for each channel, so adaptive encoding/decoding may not be sufficiently performed. Accordingly, there may be a limit in achieving optimal compression efficiency in various data types or bit rate environments.

As an embodiment, a method may be provided that excludes latent representations of a channel for efficiently encoding/decoding a latent representation from an encoding target in a deep learning-based AI compression model.

As an embodiment, a channel in which all elements are 0 in an input Latent Representation may be detected, and a corresponding channel may be excluded from an encoding target.

As an embodiment, an additional flag (Skip Flag) representing whether a channel is skipped may be generated and included in encoding information. A Skip Flag may be expressed in the form of a binary vector representing whether each channel is active, and may be transmitted together during an encoding process. A Skip Flag may be stored as the separate header information of a compressed data stream or may be integrated with encoded data and transmitted together.

As an embodiment, entropy encoding may be performed by selecting only an active channel.

As an embodiment, during decoding, Skip Flag information may be utilized to restore an excluded channel and reconstruct the entire Latent Representation. Based on a Skip Flag, decompressed data may be restored to its original dimension. The restored data may be used as the input of a decoder to effectively reconstruct the original data.

As an embodiment, a Skip Flag may be utilized as information for controlling whether to perform selective encoding in a channel unit, and whether to include encoding for each channel may be determined according to the flag.

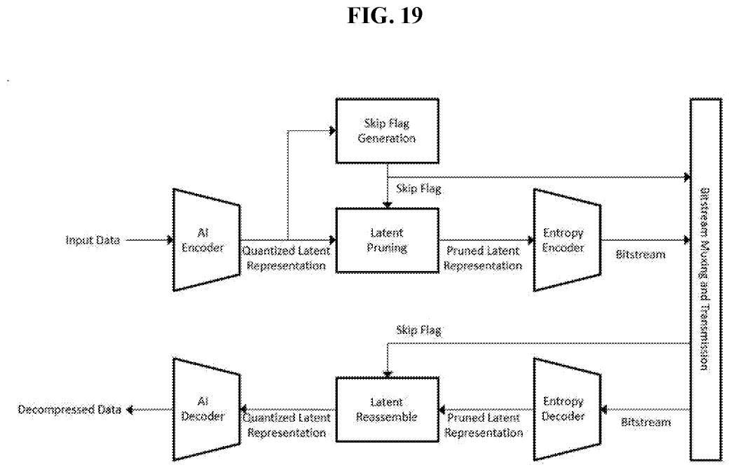

FIG. 19 illustrates an embodiment of a block diagram for a channel skip-based latent representation encoding/decoding method.

A block diagram for a channel skip-based latent representation encoding/decoding method may include an AI Encoder, an Entropy Encoder, Skip Flag Generation, Latent Pruning, Bitstream Muxing and Transmission, an Entropy Decoder, Latent Reassemble and an AI Decoder.

As an embodiment, an AI Encoder may convert input data into a Latent Representation.

As an embodiment, Skip Flag Generation may generate a Skip Flag by determining whether each channel is active in a latent representation.

As an embodiment, Latent Pruning may generate a Pruned Latent Representation by removing an inactive channel based on a Skip Flag.

As an embodiment, an Entropy Encoder may encode a Pruned Latent Representation.

As an embodiment, Bitstream Muxing and Transmission may generate and transmit a bitstream including a Skip Flag and encoded data.

As an embodiment, an Entropy Decoder may decode data from a received bitstream.

As an embodiment, Latent Reassemble may use a Skip Flag to restore a Pruned Latent Representation to its original dimension.

As an embodiment, an AI Decoder may reconstruct the original data by using a restored latent representation.

A Skip Flag may be a binary vector that identifies and records an inactive (zero-out) channel in a latent representation. A Skip Flag represents whether it is active in a channel unit, and may play an essential role in data compression and restoration processes.

As an embodiment, a Skip Flag may be composed of a one-dimensional binary vector with a length of C (the total number of channels), and a value of 1 may refer to an active channel and a value of 0 may refer to an inactive channel.

As an embodiment, a Skip Flag may be used to exclude an unnecessary channel during compressed transmission and restore it to its original dimension after decoding.

As an embodiment, for Skip Flag=[1, 0, 1, 1, 0, 1, 0, 0], channels marked as 0 in the examples may be excluded from encoding and transmission processes.

A Pruned Latent Representation may be a latent representation that excludes an inactive channel and includes only an active channel based on a Skip Flag.

As an embodiment, a Pruned Latent Representation may be composed of tensors in the form of (N, C_active, D, H, W), and C_active may refer to the number of active channels marked as 1 in a Skip Flag.

As an embodiment, a Pruned Latent Representation may be transmitted in a form in which an inactive channel is removed to improve the compression rate, and may be restored to its original dimension by using a Skip Flag during a decoding process.

As an embodiment, the following example may be considered.
Original Latent Representation Shape: (N, 8, D, H, W)
Skip Flag: [1, 0, 1, 1, 0, 1, 0, 0]
Pruned Latent Representation Shape: (N, 4, D, H, W)

In the example, as only a channel with a value of 1 is maintained and a channel with a value of 0 is removed in a Skip Flag, only 4 channels among a total of 8 channels may be selected to construct a Pruned Latent Representation.

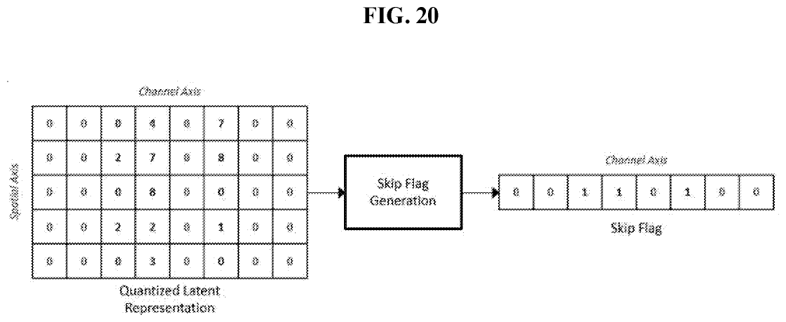

FIG. 20 illustrates an embodiment of the operation of a Skip Flag Generation module.

A Skip Flag Generation module may analyze each channel of an input Quantized Latent Representation to identify a channel where all elements are 0 and generate a Skip Flag in the form of a Binary Vector.

As an embodiment, a Quantized Latent Representation may be composed of multidimensional data including a spatial axis and a channel axis, and each channel may be understood as unit data arranged along a channel axis.

As an embodiment, for each channel, it may be determined whether all element values constructing a corresponding channel are 0, and when all elements are 0, a corresponding channel may be determined as an inactive channel.

As an embodiment, when a channel is determined as an inactive channel, a Skip Flag value corresponding to a corresponding channel may be set as 0, and when it is determined as an active channel, a Skip Flag value may be set as 1.

As an embodiment, a Skip Flag generated through a process described above may be expressed in the form of a Binary Vector corresponding to the order of each channel.

Referring to the example of FIG. 20, since all element values included in the first channel of a channel axis are 0, a corresponding channel is determined as an inactive channel, and accordingly, it may be confirmed that the first value of a Binary Vector is set as 0. In addition, since the third channel of a channel axis includes a non-zero value, it is determined as an active channel, and accordingly, it may be confirmed that the third value of a Binary Vector is set as 1. As such, a determination on each channel may be performed to generate a Skip Flag in the form of a Binary Vector corresponding to the channel order.

As an embodiment, a generated Skip Flag may be used in subsequent Latent Pruning and encoding processes.

As an embodiment, a Skip Flag Generation module may generate a Skip Flag by processing each channel included in an input Quantized Latent Representation sequentially or in parallel.

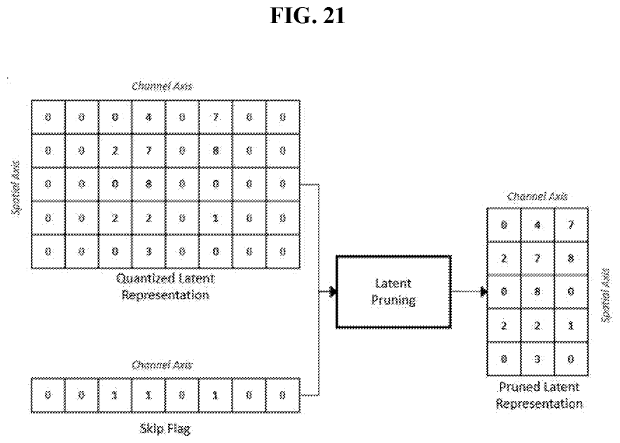

FIG. 21 illustrates an embodiment of the operation of a Latent Pruning module.

A Latent Pruning module may perform the role of removing an inactive channel from a Quantized Latent Representation by selecting only an active channel marked as 1 in a Skip Flag and generating a Pruned Latent Representation.

As an embodiment, each value of a Skip Flag represents whether it is active in a channel unit, and when a value is 1, a corresponding channel may be maintained and when a value is 0, a corresponding channel may be removed.

As an embodiment, a Latent Pruning module may construct a new latent representation (Pruned Latent Representation) by selecting only data corresponding to an active channel according to a Skip Flag. A Pruned Latent Representation may be constructed in the form of including only an active channel, and may be expressed in a form in which the number of channels is reduced. Referring to the example of FIG. 21, it may be confirmed that in a Skip Flag, only data corresponding to a channel where a value is set as 1 is maintained and data corresponding to a channel where a value is set as 0 is removed.

As an embodiment, a Pruned Latent Representation generated in this way may be an entropy encoding target.

As an embodiment, a selective removal process in a channel unit described above may be implemented in a manner that controls whether to include encoding for each channel, and may be connected to a process that determines whether to perform encoding in a channel unit.

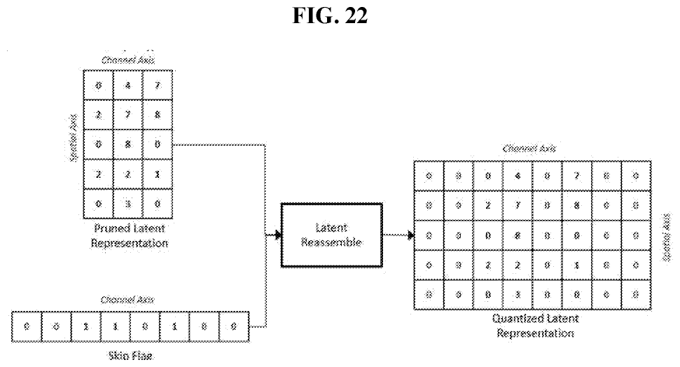

FIG. 22 illustrates an embodiment of the operation of a Latent Reassemble module.

A Latent Reassemble module may perform the role of restoring a Pruned Latent Representation to its original channel structure by utilizing a Skip Flag.

As an embodiment, a Pruned Latent Representation may be constructed in the form of including only an active channel, and may be present in a state in which some channels are removed.

As an embodiment, a Latent Reassemble module may determine the position of each channel based on the value of a Skip Flag and rearrange data included in a Pruned Latent Representation at a corresponding position.

As an embodiment, in a Skip Flag, a channel with a value of 1 may be restored by using data included in a Pruned Latent Representation and a channel with a value of 0 may be filled with a value of 0.

As an embodiment, referring to the example of FIG. 22, it may be confirmed that in a Skip Flag, a channel where a value is set as 0 is filled with 0 and a channel where a value is set as 1 inserts the data of a Pruned Latent Representation at a corresponding position.

As an embodiment, a Quantized Latent Representation having the original number of channels may be reconstructed through such a process.

As an embodiment, a reconstructed Quantized Latent Representation may be used subsequently as the input of a Decoder and used to restore the original data.

The present disclosure may provide a method for improving compression performance by effectively excluding an inactive channel from a deep learning-based compression model.

An inactive channel may be identified by using a Skip Flag, and the generation of unnecessary bits may be reduced by excluding a corresponding channel from an encoding target. A Skip Flag is transmitted together during an encoding process, and may be used to restore an original channel structure during a decoding process.

In addition, a Pruned Latent Representation may be generated and transmitted to reduce a data size and improve compression efficiency.

In addition, decoded data may be restored to its original dimension through a Latent Reassemble process, and based on this, the original data may be effectively reconstructed.

Accordingly, the present disclosure may reduce computational complexity and improve processing speed by reducing the amount of data that needs to be processed during encoding and decoding processes. In addition, the present disclosure may support adaptive data compression by selectively performing encoding in a channel unit according to the characteristics of input data. In addition, the present disclosure may be applied to data compression in various forms such as images, videos, audio, 3D data, etc.

As an embodiment, the technique of the present disclosure may be applied without changing an existing learned AI compression model and may improve compression efficiency without additional learning.

Although the exemplary methods of the present disclosure are expressed as a series of operations for clarity of description, this is not intended to limit the order in which steps are performed, and if necessary, each step may be performed simultaneously or in different order. In order to implement a method according to the present disclosure, another step may be additionally included in an exemplary step or the remaining steps may be included excluding some steps or another additional step may be included excluding some steps.

The various embodiments of the present disclosure do not list all possible combinations, but are intended to describe the representative aspect of the present disclosure, and matters described in various embodiments may be applied independently or in a combination of at least two.

In addition, the various embodiments of the present disclosure may be implemented by hardware, firmware, software or a combination thereof. For implementation by hardware, they may be implemented by one or more ASICs (Application Specific Integrated Circuits), DSPs (Digital Signal Processors), DSPDs (Digital Signal Processing Devices), PLDs (Programmable Logic Devices), FPGAs (Field Programmable Gate Arrays), general processors, controllers, microcontrollers, microprocessors, etc.

The range of the present disclosure includes software or machine-executable instructions (i.e., an operating system, an application, firmware, a program, etc.) that enable operations according to the methods of various embodiments to be executed on a device or computer, and a non-transitory computer-readable medium in which such software or instructions are stored and executable on a device or computer.

1. A method for decoding a latent representation, the method comprising:
obtaining flag information representing whether each channel is active from a bitstream;
based on the flag information, obtaining data corresponding to an active channel; and
based on the flag information, reconstructing a latent representation having an overall channel structure by filling an inactive channel with a predetermined value.

2. The method of claim 1, wherein:
the flag information is constructed in a form of a binary vector representing the whether each channel is active.

3. The method of claim 1, wherein:
the inactive channel is filled with a value of 0.

4. The method of claim 1, wherein:
the data corresponding to the active channel is restored through entropy decoding.

5. The method of claim 1, wherein:
the reconstruction step includes inserting the data corresponding to the active channel and filling the inactive channel to form the overall channel structure.

6. The method of claim 1, wherein:
the flag information is used as control information for performing selective decoding in a channel unit.

7. A method for encoding a latent representation, the method comprising:
determining whether each channel is active by analyzing each channel of the latent representation; and
based on the whether each channel is active, generating a bitstream by performing entropy encoding on data corresponding to an active channel,
wherein the bitstream includes flag information representing the whether each channel is active.

8. The method of claim 7, wherein:
the flag information is constructed in a form of a binary vector representing the whether each channel is active.

9. The method of claim 7, wherein:
data corresponding to a channel determined as an inactive channel according to the whether each channel is active is excluded from an encoding target.

10. The method of claim 7, wherein:
the entropy encoding is performed based on a probability model or a context-based model.

11. The method of claim 7, wherein:
the bitstream is generated by including only the data corresponding to the active channel.

12. The method of claim 7, wherein:
the flag information is used as control information for performing selective encoding in a channel unit.

13. A non-transitory computer readable recording medium for storing a bitstream generated by a latent representation encoding method, wherein the latent representation encoding method comprises:
determining whether each channel is active by analyzing each channel of a latent representation; and
based on the whether each channel is active, generating the bitstream by performing entropy encoding on data corresponding to an active channel,
wherein the bitstream includes flag information representing the whether each channel is active.
